(19) United States
(12) Patent Application Publication
(10) Pub. No.: US 2025/0089533 A1
(43) Pub. Date: Mar. 13, 2025

(54) DISPLAY PANEL AND METHOD OF PROVIDING THE SAME

(71) Applicant: Samsung Display Co., Ltd., Yongin-si (KR)

(72) Inventor: HYUNEOK SHIN, Yongin-si (KR)

(21) Appl. No.: 18/752,916

(22) Filed: Jun. 25, 2024

(30) Foreign Application Priority Data
Sep. 8, 2023 (KR) 10-2023-0119942

(51) Int. Cl. H10K 59/80; H10K 59/12; H10K 59/122; H10K 59/35

(52) U.S. Cl. CPC H10K 59/873; H10K 59/1201; H10K 59/122; H10K 59/35

(57) ABSTRACT

A display panel includes a pixel-defining layer in which first and second light-emitting openings are defined, a partition wall in which first and second partition wall openings are defined, a first light-emitting element in the first partition wall opening, a second light-emitting element in the second partition wall opening, a first lower inorganic encapsulation pattern which covers the first light-emitting element, and a second lower inorganic encapsulation pattern which is spaced apart from the first lower inorganic encapsulation pattern and covers the second light-emitting element A thickness of the first lower inorganic encapsulation pattern is smaller than a thickness of the second lower inorganic encapsulation pattern.

This U.S. non-provisional patent application claims priority to Korean Patent Application No. 10-2023-0119942, filed on Sep. 8, 2023, and all the benefits accruing therefrom under 35 U.S.C. § 119, the entire contents of which are hereby incorporated by reference.

### BACKGROUND

### (1) Field

The present disclosure herein relates to a display panel and a method of providing the display panel. More particularly, the present disclosure relates to a display panel with improved display quality.

### (2) Description of the Related Art

A display device that provides an image to a user, such as a television, a monitor, a smartphone, and a tablet computer, includes a display panel for displaying the image. Various display panels are being developed such as a liquid crystal display panel, an organic light-emitting display panel, an electrowetting display panel, and an electrophoretic display panel.

The organic light-emitting display panel may include an anode, a cathode, and a light-emitting pattern in a light-emitting element among light-emitting regions. The light-emitting pattern may be separated for each light-emitting region, and the cathode may provide a common voltage to the light-emitting regions.

### SUMMARY

The present disclosure provides a display panel with improved display quality, in which a light-emitting element is provided (or formed) without using a metal mask, and a method for providing (or manufacturing) the display panel.

An embodiment of the invention provides a display panel including a base layer, a pixel-defining film which is disposed on the base layer, and in which a first light-emitting opening and a second light-emitting opening are defined, a partition wall which is disposed on the pixel-defining film, and in which a first partition wall opening overlapping the first light-emitting opening and a second partition wall opening overlapping the second light-emitting opening are defined, a first light-emitting element disposed in the first partition wall opening, and including a first anode, a first light-emitting pattern, and a first cathode, a second light-emitting element disposed in the second partition wall opening, and including a second anode, a second light-emitting pattern, and a second cathode, a first lower inorganic encapsulation pattern which covers the first light-emitting element, and a second lower inorganic encapsulation pattern which covers the second light-emitting element, where a thickness of the first lower inorganic encapsulation pattern is smaller than a thickness of the second lower inorganic encapsulation pattern.

In an embodiment, the first light-emitting element may emit blue light, and the second light-emitting element may emit green light.

In an embodiment, the thickness of the first lower inorganic encapsulation pattern may be about 0.2 (micrometer) μm to about 1.0 μm.

In an embodiment, the thickness of the second lower inorganic encapsulation pattern may be about 1.0 μm to about 1.5 micrometers (μm).

In an embodiment, a first dummy region may be defined between the first lower inorganic encapsulation pattern and the partition wall defining the first partition wall opening, and a second dummy region may be defined between the second lower inorganic encapsulation pattern and the partition wall defining the second partition wall opening.

In an embodiment, a height of the first dummy region may be smaller than a height of the second dummy region.

In an embodiment, a third light-emitting opening may be further defined in the pixel-defining film, and a third partition wall opening overlapping the third light-emitting opening may be further defined in the partition wall. The display panel may further include a third light-emitting element disposed in the third partition wall opening, and including a third anode, a third light-emitting pattern, and a third cathode, and a third lower inorganic encapsulation pattern which covers the third light-emitting element.

In an embodiment, a thickness of the third lower inorganic encapsulation pattern may be equal to or greater than the thickness of the second lower inorganic encapsulation pattern.

In an embodiment, the third light-emitting element may emit red light.

In an embodiment, the third lower inorganic encapsulation pattern may have a thickness of about 1.0 μm to about 1.7 μm.

In an embodiment, a third dummy region may be defined between the third lower inorganic encapsulation pattern and the partition wall defining the third partition wall opening.

In an embodiment, a height of the third dummy region may be greater than a height of the second dummy region.

In an embodiment of the invention, a manufacturing method for a display panel includes providing a preliminary display panel including a base layer, a pixel-defining film disposed on the base layer, a first preliminary partition wall layer disposed on the pixel-defining film, and a second preliminary partition wall layer disposed on the first preliminary partition wall layer, etching the first preliminary partition wall layer and the second preliminary partition wall layer to form a partition wall in which a first partition wall opening, a second partition wall opening, and a third partition wall opening are defined, forming a first light-emitting element in the first partition wall opening, forming a first lower inorganic encapsulation pattern which covers the first light-emitting element, forming a second light-emitting element in the second partition wall opening, forming a second lower inorganic encapsulation pattern which covers the second light-emitting element, forming a third light-emitting element in the third partition wall opening, and forming a third lower inorganic encapsulation pattern which covers the third light-emitting element, and a thickness of the first lower inorganic encapsulation pattern may be smaller than a thickness of the second lower inorganic encapsulation pattern.

In an embodiment, a thickness of the third lower inorganic encapsulation pattern may be equal to or greater than the thickness of the second lower inorganic encapsulation pattern.

In an embodiment, the forming of the first light-emitting element in the first partition wall opening may include forming a first dummy layer inside the second and third partition wall openings and on the partition wall.

In an embodiment, the forming of the first lower inorganic encapsulation pattern which covers the first light-emitting element may include depositing a first lower inorganic encapsulation layer to cover the first to third partition wall openings and the partition wall, and to have a thickness of about 0.2 μm to about 1.0 μm, removing a portion of the first lower inorganic encapsulation layer not overlapping the first light-emitting element, and removing the first dummy layer to form a first dummy region between the first lower inorganic encapsulation pattern and the partition wall defining the first partition wall opening.

In an embodiment, the forming of the second light-emitting element in the second partition wall opening may include forming a second dummy layer inside the first and third partition wall openings and on the partition wall.

In an embodiment, the forming of the second lower inorganic encapsulation pattern which covers the second light-emitting element may include depositing a second lower inorganic encapsulation layer to cover the first to third partition wall openings and the partition wall, and to have a thickness of about 1.0 μm to about 1.5 μm, removing a portion of the second lower inorganic encapsulation layer not overlapping the second light-emitting element, and removing the second dummy layer to form a second dummy region between the second lower inorganic encapsulation pattern and the partition wall defining the second partition wall opening.

In an embodiment, the forming of the third light-emitting element in the third partition wall opening may include forming a third dummy layer inside the first and second partition wall openings and on the partition wall.

In an embodiment, the forming of the third lower inorganic encapsulation pattern which covers the third light-emitting element may include depositing a third lower inorganic encapsulation layer to cover the first to third partition wall openings and the partition wall, and to have a thickness of about 1.0 μm to about 1.7 μm, removing a portion of the third lower inorganic encapsulation layer not overlapping the third light-emitting element, and removing the third dummy layer to form a third dummy region between the third lower inorganic encapsulation pattern and the partition wall defining the third partition wall opening.

### BRIEF DESCRIPTION OF THE FIGURES

The accompanying drawings are included to provide a further understanding of the invention, and are incorporated in and constitute a part of this specification. The drawings illustrate embodiments of the invention and, together with the description, serve to explain principles of the invention. In the drawings:

FIG. 1A is a perspective view of a display device according to an embodiment of the invention;

FIG. 1B is an exploded perspective view of a display device according to an embodiment of the invention;

FIG. 2 is a cross-sectional view of a display module according to an embodiment of the invention;

FIG. 3 is a plan view of a display panel according to an embodiment of the invention;

FIG. 4 is an equivalent circuit diagram of a pixel according to an embodiment of the invention;

FIG. 5 is an enlarged plan view illustrating a portion of a display region of a display panel according to an embodiment of the invention;

FIG. 6 is a cross-sectional view of a display panel, according to an embodiment of the invention, taken along line I-I′ of FIG. 3;

FIG. 7 is a cross-sectional view taken along line II-II′ of FIG. 5; and

FIGS. 8A to 8I, 9A to 9D, 10A to 10D and 11 are cross-sectional views illustrating processes of a method of manufacturing (or providing) a display panel according to an embodiment of the invention.

### DETAILED DESCRIPTION

In this specification, it will be understood that when an element (or a region, a layer, a portion, or the like) is referred to as being related to another element such as being “on”, “connected to”, “coupled to” another element, it may be directly disposed on, connected or coupled to the other element, or intervening elements may be disposed therebetween. In contrast, when an element (or a region, a layer, a portion, or the like) is referred to as being related to another element such as being “directly on”, “directly connected to”, “directly coupled to” another element, no intervening element is disposed therebetween. As used herein, elements in contact with each other may form an interface therebetween.

Like reference numerals or symbols refer to like elements throughout. Within the Figures and the text of the disclosure, a reference number indicating a singular form of an element may also be used to reference a plurality of the singular element. In the drawings, the thickness, the ratio, and the size of the element are exaggerated for effective description of the technical contents.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section.

The terminology used herein is for the purpose of describing particular embodiments only and is not intended to be limiting. As used herein, the singular forms, “a”, “an” and “the” are intended to include the plural forms as well, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/of” includes any and all combinations of one or more of the associated listed items.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the invention are described with reference to the accompanying drawings.

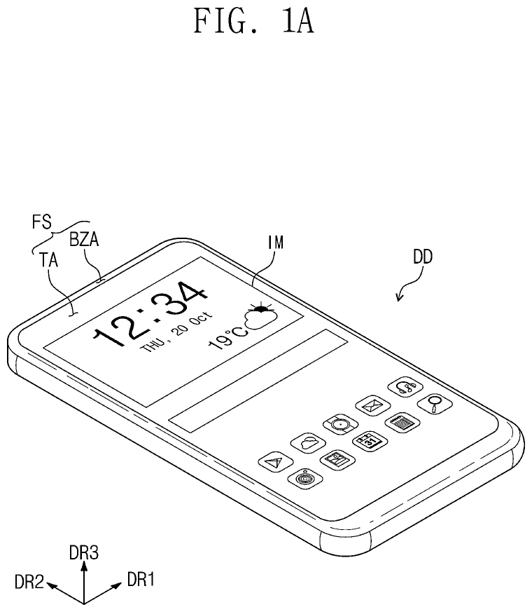

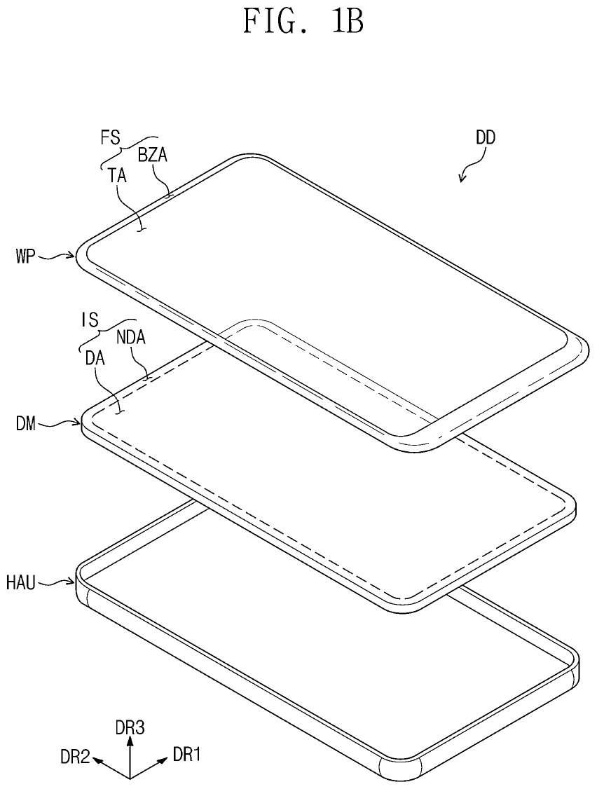

FIG. 1A is a perspective view of a display device DD according to an embodiment of the invention, and FIG. 1B is an exploded perspective view of the display device DD according to an embodiment of the invention.

In an embodiment, the display device DD may be a large electronic apparatus such as a television, a monitor, or a billboard. In addition, the display device DD may be a small- or medium-sized electronic apparatus such as a personal computer, a laptop computer, a personal digital assistant, a car navigation unit, a game console, a smartphone, a tablet computer, and a camera. However, this is an example, and another display device may also be adopted unless it departs from the idea of the invention. FIGS. 1A and 1B exemplarily illustrate the display device DD as the smartphone.

Referring to FIGS. 1A and 1B, the display device DD may display an image IM on a display surface FS disposed in a plane. The display surface FS may be parallel to a plane defined by a first direction DR1 and a second direction DR2 crossing each other. The display surface FS may be viewable along a third direction DR3, such that the image IM may be displayed toward the third direction DR3. A thickness of the display device DD and/or various components or layers thereof, may be defined along the third direction DR3 as a thickness direction.

The image IM may include a still image as well as a dynamic image. FIG. 1A illustrates a clock and icons as examples of the image IM. The display surface FS on which the image IM is displayed may correspond to a front surface of the display device DD.

In this embodiment, a front surface (or upper surface) and a rear surface (or lower surface) of each of members are defined on the basis of a direction in which the image IM is displayed. The front surface and the rear surface may be opposed to each other in the third direction DR3, and the normal direction of each of the front surface and the rear surface may be parallel to the third direction DR3. As used herein, directions indicated by the first to third directions DR1, DR2, and, DR3 may be relative concepts, and may thus be changed to other directions. In this specification, “on a plane” or “in a plan view” may refer to a state when viewed from the third direction DR3.

The display device DD may include a window WP, a display module DM, and a housing HAU. The window WP may be coupled to the housing HAU to form the exterior of the display device DD.

The window WP may include an optically transparent insulating material. For example, the window WP may include glass or plastic. A front surface of the window WP may define the display surface FS of the display device DD. The display surface FS may include a transmission region TA and a bezel region BZA. The transmission region TA may be an optically transparent region. For example, the transmission region TA may have a visible light transmittance of about 90% or more.

The bezel region BZA may be a region (or planar area) having relatively lower light transmittance than that of the transmission region TA. The bezel region BZA may define the shape (e.g., the planar shape) of the transmission region TA. The bezel region BZA may be adjacent to the transmission region TA, such as being closer to an outer edge of the display device DD than the transmission region TA. In an embodiment, the bezel region BZA may surround the transmission region TA. However, this is exemplarily illustrated, and the bezel region BZA of the window WP may be omitted. The window WP may include at least any one functional layer of an anti-fingerprint layer, a hard-coating layer, and an anti-reflection layer, and is not limited to any one embodiment of the invention.

The display module DM may be disposed under the window WP. The display module DM may be a component substantially generating the image IM. The image IM generated in the display module DM is displayed on a display surface IS of the display module DM, and viewable to outside the display device DD through the transmission region, such as to a user of the display device DD.

The display module DM may include a display region DA and a non-display region NDA. The display region DA may be activated in response to electrical signals. The non-display region NDA may be adjacent to the display region DA. The non-display region NDA may surround the display region DA. The non-display region NDA may be covered by the bezel region BZA, and may thus be invisible from the outside (e.g., the outside of the display device DD).

The housing HAU may be coupled to the window WP. The housing HAU may be coupled to the window WP to provide a predetermined inner space. The display module DM may be accommodated in the inner space.

The housing HAU may include a material relatively high in rigidity. For example, the housing HAU may include a plurality of frames and/or plates containing glass, plastic, or metal, or composed of a combination thereof. The housing HAU may stably protect components of the display device DD, accommodated in the inner space, from external impact.

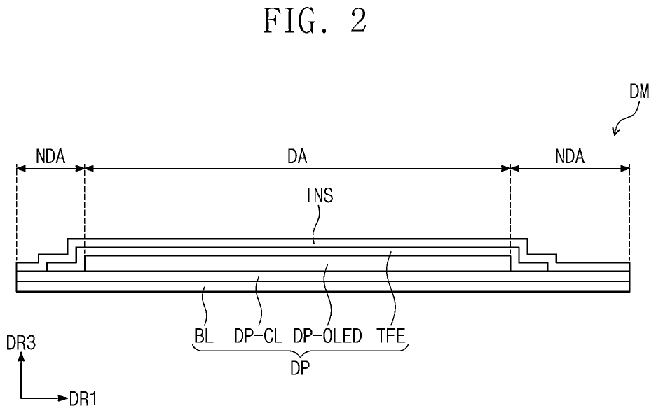

FIG. 2 is a cross-sectional view of a display module DM according to an embodiment of the invention.

Referring to FIG. 2, a display module DM may include a display panel DP as an imaging displaying layer and an input sensor INS as an input sensing layer. Although not illustrated separately in the drawing, the display device DD (see FIG. 1A), according to an embodiment of the invention, may further include a protection member disposed on a lower surface of the display panel DP, or an anti-reflection member and/or a window member disposed on an upper surface of the input sensor INS.

The display panel DP may be an emission-type display panel. However, this is an example, and an embodiment of the invention is not limited particularly thereto. For example, the display panel DP may be an organic light-emitting display panel or an inorganic light-emitting display panel. A light-emitting layer in the organic light-emitting display panel may include an organic light-emitting material. A light-emitting layer in the inorganic light-emitting display panel may include quantum dots, quantum rods, or a micro-LED. Hereinafter, the display panel DP is described as the organic light-emitting display panel.

The display panel DP may include a base layer BL, a circuit element layer DP-CL disposed on the base layer BL, a display element layer DP-OLED, and a thin-film encapsulation layer TFE as an encapsulation layer. The input sensor INS may be directly disposed on the thin-film encapsulation layer TFE. In this specification, “component A directly disposed on component B” means that there is no intervening adhesive layer disposed between component A and component B.

The base layer BL may include at least one plastic film. The base layer BL, which is a flexible substrate, may include a plastic substrate, a glass substrate, a metal substrate, an organic/inorganic composite material substrate, or the like. The display region DA and the non-display region NDA, described with reference to FIG. 1B, may be equally defined in the base layer BL. That is, various layers or components of the display device DD may include a display region DA, a non-display region NDA, etc. corresponding those described above.

The circuit element layer DP-CL may include at least one insulation layer and a circuit element. The insulation layer includes at least one inorganic layer and at least one organic layer. The circuit element includes signal lines, a driving circuit of a pixel PX, etc.

The display element layer DP-OLED may include a partition wall and a light-emitting element ED. The light-emitting element ED may include an anode AE, an intermediate layer, and a cathode CE. The light-emitting element ED may be electrically connected to the circuit element layer DP-CL.

The thin-film encapsulation layer TFE may include a plurality of thin films. Some thin films may be disposed in order to improve optical efficiency, and other thin films may be disposed in order to protect organic light-emitting diodes.

The input sensor INS acquires coordinate information of an external input to the display device DD. The input sensor INS may have a multi-layer structure. The input sensor INS may include a single-layer or multi-layer conductive layer. In addition, the input sensor INS may include a single-layer or multi-layer insulation layer. The input sensor INS may detect an external input in a capacitance manner. However, this is an example, and an embodiment of the invention is not limited thereto. For example, in an embodiment, the input sensor INS may also detect the external input in an electromagnetic induction or pressure-sensing manner. According to another embodiment of the invention, the input sensor INS may be omitted.

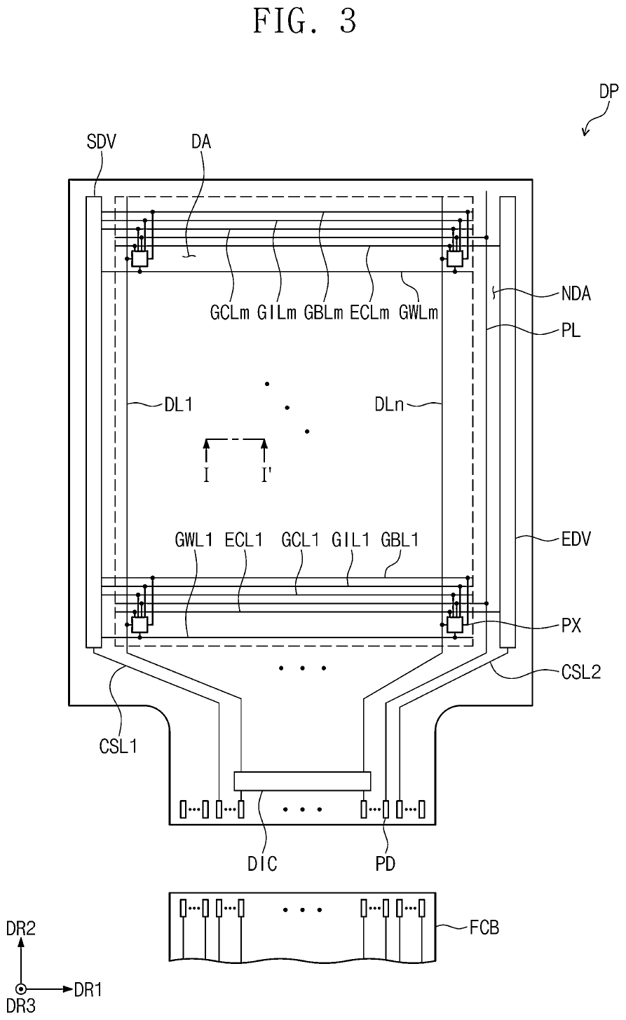

FIG. 3 is a plan view of a display panel DP according to an embodiment of the invention.

Referring to FIG. 3, a display region DA and a non-display region NDA which is around the display region DA may be defined in the display panel DP. The display region DA and the non-display region NDA may be distinguished according to whether pixels PX are disposed therein or not. The pixels PX may be disposed in the display region DA, and the pixels PX may not be disposed in the non-display region NDA.

The display panel DP may include the pixels PX, initialization scan lines GIL1 to GILm, compensation scan lines GCL1 to GCLm, write scan lines GWL1 to GWLm, black scan lines GBL1 to GBLm, emission control lines ECL1 to ECLm, data lines DL1 to DLn, first and second control lines CSL1 and CSL2, a driving voltage line PL, a scan driver SDV, a data driver, an emission driver EDV, a driving chip DIC, and pads PD. Here, ‘m’ and ‘n’ are natural numbers of at least 2. The data driver may be a partial circuit configured in the driving chip DIC.

The pixels PX may be connected to the initialization scan lines GIL1 to GILm, the compensation scan lines GCL1 to GCLm, the write scan lines GWL1 to GWLm, the black scan lines GBL1 to GBLm, the emission control lines ECL1 to ECLm, and the data lines DL1 to DLn.

The initialization scan lines GIL1 to GILm, the compensation scan lines GCL1 to GCLm, the write scan lines GWL1 to GWLm, and the black scan lines GBL1 to GBLm may extend in a first direction DR1 to be electrically connected to the scan driver SDV. The data lines DL1 to DLn may extend in a second direction DR2 to be electrically connected to the driving chip DIC. The emission control lines ECL1 to ECLm may extend in the first direction DR1 to be electrically connected to the emission driver EDV.

The driving voltage line PL may include a portion extending in the first direction DR1 and a portion extending in the second direction DR2. The portion extending in the first direction DR1 and the portion extending in the second direction DR2 may be disposed on different layers from each other within the display panel DP. The driving voltage line PL may provide a driving voltage to the pixels PX.

The first control line CSL1 may be connected to the scan driver SDV. The second control line CSL2 may be connected to the emission driver EDV.

The driving chip DIC, the driving voltage line PL, the first control line CSL1, and the second control line CSL2 may be electrically connected to the pads PD. A flexible circuit film FCB such as a circuit board may be electrically connected to the pads PD through an anisotropy conductive adhesive layer. The pads PD may be terminal pads for connecting the flexible circuit film FCB to the display panel DP. That is, the display panel DP may be electrically connected to an external component such as the circuit board, at the pads PD of the display panel DP. The pads PD may be connected to corresponding pixels PX through the driving voltage line PL, the first control line CSL1, and the second control line CSL2.

In addition, the pads PD may further include input pads. The input pads may be terminal pads for connecting the flexible circuit film FCB to the input sensor INS (see FIG. 2). That is, the external component may be connected to the input sensor INS at the input pads. However, an embodiment of the invention is not limited thereto, and the input pads may be disposed on the input sensor INS, and connected to a circuit board separately from the pads PD. In addition, the input sensor INS may be omitted, and the input pads may not be further included.

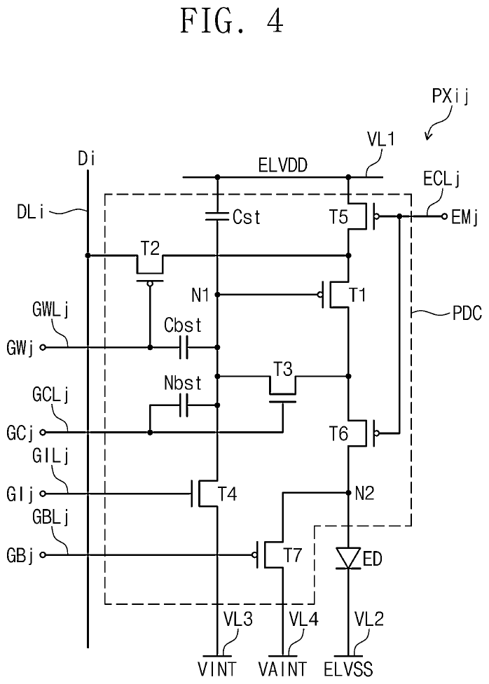

FIG. 4 is an equivalent circuit diagram of a pixel PXij according to an embodiment of the invention.

FIG. 4 exemplarily illustrates an equivalent circuit diagram of one pixel PXij among the plurality of pixels PX (see FIG. 3). Since each of the plurality of pixels PX has the same circuit structure, the description on the circuit structure of the pixel PXij may be equally applied to the remainder of the pixels PX, so that detailed descriptions thereof will be omitted.

Referring to FIGS. 3 and 4, the pixel PXij is connected to an i-th data line DLi among the data lines DL1 to DLn, a j-th initialization scan line GILj among the initialization scan lines GIL1 to GILm, a j-th compensation scan line GCLj among the compensation scan lines GCL1 to GCLm, a j-th write scan line GWLj among the write scan lines GWL1 to GWLm, a j-th black scan line GBLj among the black scan lines GBL1 to GBLm, a j-th emission control line ECLj among the emission control lines ECL1 to ECLm, first and second driving voltage lines VL1 and VL2, and first and second initialization voltage lines VL3 and VL4. Here, ‘i’ is an integer of 1 to ‘n’, and ‘j’ is an integer of 1 to ‘m’.

The pixel PXij includes a light-emitting element ED and a pixel circuit PDC. The light-emitting element ED may be a light-emitting diode. As an example of the invention, the light-emitting element ED may be an organic light-emitting diode including an organic light-emitting layer, but an embodiment of the invention is not limited particularly thereto. The pixel circuit PDC may control the amount of current (e.g., electrical current) flowing through the light-emitting element ED in response to a data signal Di. The light-emitting element ED may emit light of a predetermined brightness in response to the amount of current provided from the pixel circuit PDC.

The pixel circuit PDC may include first to seventh transistors T1, T2, T3, T4, T5, T6, and T7, and first to third capacitors Cst, Cbst, and Nbst. The configuration of the pixel circuit PDC according to an embodiment of the invention is not limited to the embodiment illustrated in FIG. 4. The pixel circuit PDC illustrated in FIG. 4 is only an example, and the configuration of the pixel circuit PDC may be variously provided.

At least one among the first to seventh transistors T1, T2, T3, T4, T5, T6, and T7 may be a transistor having a low-temperature polycrystalline silicon (LTPS) semiconductor layer. At least one among the first to seventh transistors T1, T2, T3, T4, T5, T6, and T7 may be a transistor having an oxide semiconductor layer. For example, the third and fourth transistors T3 and T4 may be oxide semiconductor transistors, and the first, second, fifth, sixth, and seventh transistors T1, T2, T5, T6, and T7 may be LTPS transistors.

In particular, the first transistor T1, which directly affects the brightness of the light-emitting element ED, may be configured to include a semiconductor layer composed of highly-reliable polycrystalline silicon, thereby achieving a high-resolution display device. Since the oxide semiconductor has high carrier mobility and low leakage current, a voltage drop is not significant despite long operation time. That is, low-frequency drive is possible since a color change of an image IM, caused by the voltage drop, is not significant even during the low-frequency drive. As previously described, since the oxide semiconductor has the advantage of low leakage current, adopting at least one of the third transistor T3 or the fourth transistor T4, connected to a gate electrode of the first transistor T1, as the oxide semiconductor may prevent leakage current from flowing into the gate electrode, and at the same time, may reduce power consumption.

Some of the first to seventh transistors T1, T2, T3, T4, T5, T6, and T7 may be P-type transistors, and the others may be N-type transistors. For example, the first, second, fifth, sixth, and seventh transistors T1, T2, T5, T6, and T7 may be P-type transistors, and the third and fourth transistors T3 and T4 may be N-type transistors.

The configuration of the pixel circuit PDC according to an embodiment of the invention is not limited to the embodiment illustrated in FIG. 4. The pixel circuit PDC illustrated in FIG. 4 is only an example and the configuration of the pixel circuit PDC may be variously provided. For example, all of the first to seventh transistors T1, T2, T3, T4, T5, T6, and T7 may be either P-type transistors or N-type transistors. Alternatively, the first, second, fifth, and sixth transistors T1, T2, T5, and T6 may be P-type transistors, and the third, fourth, and seventh transistors T3, T4, and T7 may be N-type transistors.

The j-th initialization scan line GILj, the j-th compensation scan line GCLj, the j-th write scan line GWLj, the j-th black scan line GBLj, and the j-th emission control line ECLj may respectively transmit a j-th initialization scan signal GIj, a j-th compensation scan signal GCj, a j-th write scan signal GWj, a j-th black scan signal GBj, and a j-th emission control signal EMj to the pixel PXij. An i-th data line DLi transmits an i-th data signal Di to the pixel PXij. The i-th data signal Di may have a level of voltage corresponding to an image signal input to the display device DD (see FIG. 1).

The first and second driving voltage lines VL1 and VL2 may respectively transmit a first driving voltage ELVDD and a second driving voltage ELVSS to the pixel PXij. In addition, the first and second initialization voltage lines VL3 and VL4 may respectively transmit a first initialization voltage VINT and a second initialization voltage VAINT to the pixel PXij.

The first transistor T1 is connected between the first driving voltage line VL1 which receives the first driving voltage ELVDD and the light-emitting element ED. The first transistor T1 includes a first electrode connected to the first driving voltage line VL1 via the fifth transistor T5, and a second electrode connected to a pixel electrode (or referred to as an anode AE) of the light-emitting element ED via the sixth transistor T6, and a third electrode (for example, gate electrode) connected to one end (for example, first node N1) of the first capacitor Cst. The first transistor T1 may receive the i-th data signal Di transmitted through the i-th data line DLi according to a switching operation of the second transistor T2, and provide a driving current to the light-emitting element ED.

The second transistor T2 is connected between the data line DLi and the first electrode of the first transistor T1. The second transistor T2 includes a first electrode connected to the data line DLi, a second electrode connected to the first electrode of the first transistor T1, and a third electrode (for example, gate electrode) connected to the j-th write scan line GWLj. The second transistor T2 may be turned on in response to the write scan signal GWj received through the j-th write scan line GWLj, and transmit the i-th data signal Di, transmitted through the i-th data line DLi, to the first electrode of the first transistor T1. One end of the second capacitor Cbst may be connected to the third electrode of the second transistor T2, and the other end of the second capacitor Cbst may be connected to the first node N1.

The third transistor T3 is connected between the second electrode of the first transistor T1 and the first node N1. The third transistor T3 includes a first electrode connected to the third electrode of the first transistor T1, a second electrode connected to the second electrode of the first transistor T1, and a third electrode (for example, gate electrode) connected to the j-th compensation scan line GCLj. The third transistor T3 may be turned on in response to the j-th compensation scan signal GCj transmitted through the j-th compensation scan line GCLj, and connect the third electrode of the first transistor T1 and the second electrode of the first transistor T1 to each other to make the first transistor T1 diode-connected. One end of the third capacitor Nbst may be connected to the third electrode of the third transistor T3, and the other end of the third capacitor Nbst may be connected to the first node N1.

The fourth transistor T4 is connected between the first initialization voltage line VL3, to which the first initialization voltage VINT is applied, and the first node N1. The fourth transistor T4 includes a first electrode connected to the first initialization voltage line VL3 through which the first initialization voltage VINT is transmitted, a second electrode connected to the first node N1, and a third electrode (for example, gate electrode) connected to the j-th initialization scan line GILj. The fourth transistor T4 is turned on in response to the j-th initialization scan signal GIj transmitted through the j-th initialization scan line GILj. The turned-on fourth transistor T4 transfers the first initialization voltage VINT to the first node N1, and thus initializes the potential of the third electrode of the first transistor T1 (that is, the potential of the first node N1).

The fifth transistor T5 includes a first electrode connected to the first driving voltage line VL1, a second electrode connected to the first electrode of the first transistor T1, and a third electrode (for example, gate electrode) connected to the j-th emission control line ECLj. The sixth transistor T6 includes a first electrode connected to the second electrode of the first transistor T1, a second electrode connected to the pixel electrode of the light-emitting element ED, and a third electrode (for example, gate electrode) connected to the j-th emission control line ECLj.

The fifth and sixth transistors T5 and T6 are turned on simultaneously in response to the j-th emission control signal EMj transmitted through the j-th emission control line ECLj. The first driving voltage ELVDD applied through the turned-on fifth transistor T5 may be compensated through the diode-connected first transistor T1, and then transferred to the light-emitting element ED through the sixth transistor T6.

The seventh transistor T7 includes a first electrode connected to the second initialization voltage line VL4 through which the second initialization voltage VAINT is transmitted, a second electrode connected to the second electrode of the sixth transistor T6, and a third electrode (for example, gate electrode) connected to the j-th black scan line GBLj. The second initialization voltage VAINT may have a level of voltage lower than or equal to that of the first initialization voltage VINT.

The one end of the first capacitor Cst is connected to the third electrode of the first transistor T1, and the other end of the first capacitor Cst is connected to the first driving voltage line VL1. A cathode CE of the light-emitting element ED may be connected to the second driving voltage line VL2 through which the second driving voltage ELVSS is transmitted. The second driving voltage ELVSS may have a level of voltage lower than that of the first driving voltage ELVDD.

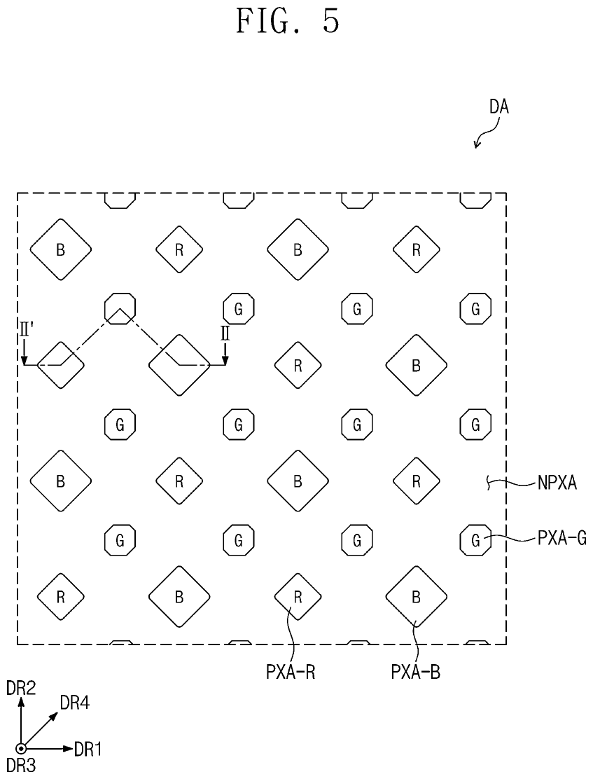

FIG. 5 is an enlarged plan view illustrating a portion of a display region DA of the display panel DP (see FIG. 2) according to an embodiment of the invention. FIG. 5 illustrates a plan view of a display module DM when viewed from the display surface IS (see FIG. 1B) of the display module DM (see FIG. 1B), and illustrates arrangement of light-emitting regions PXA-B, PXA-G, and PXA-R.

Referring to FIG. 5, the display region DA may include a light-emitting region and a non-emitting region which is adjacent to the light-emitting region. The light-emitting region may be provided in plural including first to third light-emitting regions PXA-B, PXA-G, and PXA-R, and the non-emitting region may include a peripheral region NPXA surrounding the first to third light-emitting regions PXA-B, PXA-G, and PXA-R. The first to third light-emitting regions PXA-B, PXA-G, and PXA-R may respectively correspond to regions (or planar areas) where light provided from light-emitting elements is emitted. The first to third light-emitting regions PXA-B, PXA-G, and PXA-R may be distinguished according to colors of light emitted toward the outside of the display module DM (see FIG. 2).

The first to third light-emitting regions PXA-B, PXA-G, and PXA-R may respectively provide first to third color light having different colors from each other. For example, the first color light may be blue light, the second color light may be green light, and the third color light may be red light. However, examples of the first to third color light are not limited necessarily to the embodiment of the invention.

The first to third light-emitting regions PXA-B, PXA-G, and PXA-R may each be defined as a region where an upper surface of an anode AE is exposed by a light-emitting opening OP-E to be described later. That is, a planar area of a respective light-emitting region may correspond to a planar area of the anode AE which is exposed to outside a pixel-defining layer. The peripheral region NPXA may set boundaries of the first to third light-emitting regions PXA-B, PXA-G, and PXA-R, and prevent color mixing between the first to third light-emitting regions PXA-B, PXA-G, and PXA-R.

The first to third light-emitting regions PXA-B, PXA-G, and PXA-R may each be provided in plurality, and repeatedly disposed in a predetermined arrangement within the display region DA. For example, the first and third light-emitting regions PXA-B and PXA-R may be alternately arranged along a first direction DR1 to form a ‘first group’. The second light-emitting regions PXA-G may be arranged along the first direction DR1 to form a ‘second group’. The ‘first group’ and the ‘second group’ may each be provided in plurality, and the ‘first groups’ and the ‘second groups’ may be alternately arranged along a second direction DR2.

One second light-emitting region PXA-G may be disposed apart from one first light-emitting region PXA-B or one third light-emitting region PXA-R in a fourth direction DR4. The fourth direction DR4 may be defined as a direction between the first and second directions DR1 and DR2, such as a direction inclined with respect to the first or second directions DR1 and DR2.

FIG. 5 illustrates the arrangement of the first to third light-emitting regions PXA-B, PXA-G, and PXA-R as an example, an embodiment of the invention is not limited thereto, and the arrangement may have various forms. In an embodiment, the first to third light-emitting regions PXA-B, PXA-G, and PXA-R may have a PENTILE™ arrangement form as illustrated in FIG. 5. Alternatively, the first to third light-emitting regions PXA-B, PXA-G, and PXA-R may also have a stripe arrangement form, or a Diamond Pixel™ arrangement form.

The first to third light-emitting regions PXA-B, PXA-G, and PXA-R may have various shapes on a plane. For example, the first to third light-emitting regions PXA-B, PXA-G, and PXA-R may have a planar shape of a polygonal, circular, oval shape, or the like. FIG. 5 exemplarily illustrates the first and third light-emitting regions PXA-B and PXA-R in a quadrilateral shape (or diamond shape), and the second light-emitting region PXA-G in an octagonal shape on a plane.

The first to third light-emitting regions PXA-B, PXA-G, and PXA-R may have the same shape on a plane, and alternatively, at least some may have different shapes. FIG. 5 exemplarily illustrates the first and third light-emitting regions PXA-B and PXA-R having the same shape, and the second light-emitting region PXA-G having a different shape from the first and third light-emitting regions PXA-B and PXA-R on a plane.

At least some among the first to third light-emitting regions PXA-B, PXA-G, and PXA-R may have different areas on a plane. In an embodiment, the area of the third light-emitting region PXA-R which emits the red light may be larger than the area of the second light-emitting region PXA-G which emits the green light, and smaller than the area of the first light-emitting region PXA-B which emits the blue light. However, the size relationship of the areas between the first to third light-emitting regions PXA-B, PXA-G, and PXA-R according to the light-emitting colors is not limited thereto, and may vary according to the design of the display module DM (see FIG. 2). In addition, an embodiment of the invention is not limited thereto, and the first to third light-emitting regions PXA-B, PXA-G, and PXA-R may have the same area on a plane.

The shape, the area, the arrangement, etc. of the first to third light-emitting regions PXA-B, PXA-G, and PXA-R of the display module DM (see FIG. 2), according to an embodiment of the invention, may be variously designed according to the color of light emitted, the size and composition of the display module DM (see FIG. 2), and are not limited to the embodiment illustrated in FIG. 5.

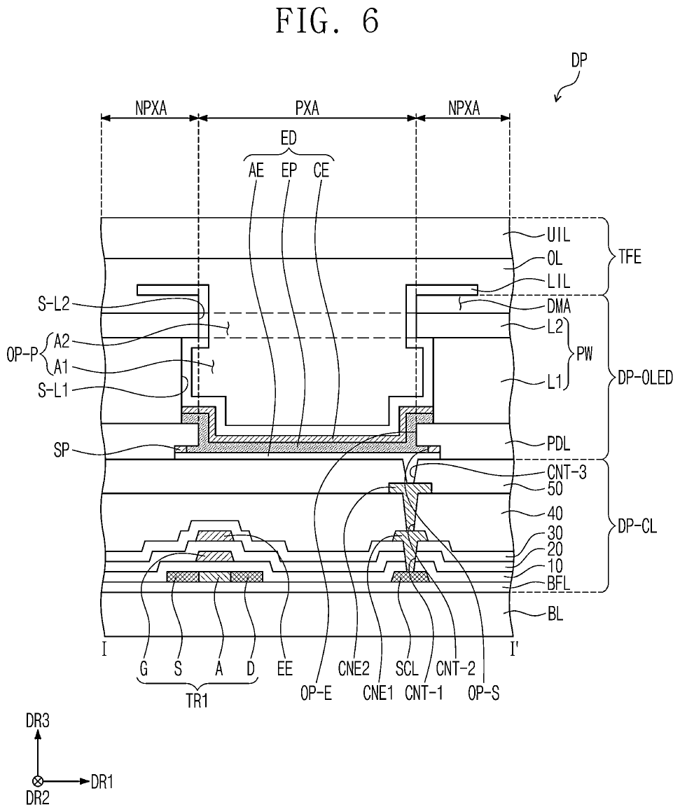

FIG. 6 is a cross-sectional view of a display panel DP, according to an embodiment of the invention, taken along line I-I′ of FIG. 3. FIG. 6 will be described with reference to FIG. 2, and descriptions of the same reference numerals or symbols will be omitted.

FIG. 6 is an enlarged view of one light-emitting region PXA in the display region DA (see FIG. 5), and the light-emitting region PXA in FIG. 6 may correspond to any one among the first to third light-emitting regions PXA-B, PXA-G, and PXA-R in FIG. 5. Referring to FIG. 6, a display panel DP may include a base layer BL, a circuit element layer DP-CL, a display element layer DP-OLED, and a thin-film encapsulation layer TFE.

The display panel DP may include a plurality of insulation layers, a semiconductor pattern, a conductive pattern, a signal line, etc., which are on the base layer BL Material layers of the insulation layer, a semiconductor layer, and a conductive layer are formed (or provided) through coating, deposition, etc. After this, the material layers forming the insulation layer, the semiconductor layer, and the conductive layer may be selectively patterned through photolithography and etching. In such ways, the semiconductor pattern, the conductive pattern, the signal line, etc., included in the circuit element layer DP-CL and the display element layer DP-OLED, may be formed as respective patterns of the material layer.

The circuit element layer DP-CL may be disposed on the base layer BL. The circuit element layer DP-CL may include a buffer layer BFL, a transistor TR1, a signal transmission line SCL, first to fifth insulation layers 10, 20, 30, 40, and 50, an electrode EE, and a plurality of connection electrodes CNE1 and CNE2.

The buffer layer BFL may be disposed on the base layer BL. The buffer layer BFL may improve bonding forces between the base layer BL and the semiconductor pattern. The buffer layer BFL may include a silicon oxide layer and a silicon nitride layer. The silicon oxide layer and the silicon nitride layer may be alternately stacked.

The semiconductor pattern may be disposed on the buffer layer BFL. The semiconductor pattern may include polysilicon. However, an embodiment of the invention is not limited thereto, and the semiconductor pattern may include amorphous silicon or metal oxide. FIG. 6 illustrates a partial semiconductor pattern only as an example, and the semiconductor pattern may further be disposed in the plurality of light-emitting regions PXA-R, PXA-G, and PXA-B (see FIG. 5). The semiconductor pattern may be arranged in a certain rule across the plurality of light-emitting regions PXA-B, PXA-G, and PXA-R. The semiconductor pattern may vary in electrical property according to whether an area thereof is doped or not. The semiconductor pattern may include a first region doped with high concentration and a second region doped with low concentration. The first region may be doped with an N-type dopant or a P-type dopant. A P-type transistor may include the first region doped with the P-type dopant.

The first region may have higher conductivity (e.g., electrical conductivity) than that of the second region, and substantially serve as a conductive electrode or an electrical signal line. The second region may substantially correspond to an active (or channel) of the transistor. In other words, a portion of the semiconductor pattern may be the active of the transistor, another portion may be a source or a drain of the transistor, and another portion may be a conductive region.

The source S, the active A, and the drain D of the transistor TR1 may be formed from a same one of the semiconductor pattern. FIG. 6 illustrates a portion of the signal transmission line SCL formed from the semiconductor pattern. Although not illustrated separately in the drawing, the signal transmission line SCL may be connected to the drain D of the transistor TR1 on a plane. That is, the source S, the active A, the drain D and the signal transmission line SCL may be in a same layer as each other. As being in a same layer, elements may be formed in a same process and/or include a same material as each other, elements may be respective portions or patterns of a same material layer, elements may be on a same layer by forming an interface with a same underlying or overlying layer, etc., without being limited thereto.

The first to fifth insulation layers 10, 20, 30, 40, and 50 may be disposed on the buffer layer BFL. The first to fifth insulation layers 10, 20, 30, 40, and 50 may each be an inorganic layer or an organic layer.

A first insulation layer 10 may be disposed on the buffer layer BFL. The first insulation layer 10 may cover the source S, the active A, and the drain D of the transistor TR1, and the signal transmission line SCL which are disposed on the buffer layer BFL. A gate G of the transistor TR1 may be disposed on the first insulation layer 10. A second insulation layer 20 may be disposed on the first insulation layer 10 to cover the gate G. The electrode EE may be disposed on the second insulation layer 20. A third insulation layer 30 may be disposed on the second insulation layer 20 and cover the electrode EE.

The first connection electrode CNE1 may be disposed on the third insulation layer 30. The first connection electrode CNE1 may be connected to the signal transmission line SCL through a contact hole CNT-1 passing through the first to third insulation layers 10, 20, and 30. A fourth insulation layer 40 may be disposed on the third insulation layer 30 to cover the first connection electrode CNE1. The fourth insulation layer 40 may be an organic layer.

A second connection electrode CNE2 may be disposed on the fourth insulation layer 40. The second connection electrode CNE2 may be connected to the first connection electrode CNE1 through a contact hole CNT-2 passing through the fourth insulation layer 40. A fifth insulation layer 50 may be disposed on the fourth insulation layer 40 to cover the second connection electrode CNE2. The fifth insulation layer 50 may be an organic layer.

The display element layer DP-OLED may be disposed on the circuit element layer DP-CL. The display element layer DP-OLED may include a light-emitting element ED, a sacrificial pattern SP, a pixel-defining film PDL as a pixel-defining layer, and a partition wall PW of a bank layer.

The light-emitting element ED may include an anode AE (or first electrode), a light-emitting pattern EP, and a cathode CE (or second electrode).

The anode AE may be disposed on the fifth insulation layer 50 of the circuit element layer DP-CL. The anode AE may be a transmissive electrode, a semi-transmissive electrode, or a reflective electrode. The anode AE may be connected to the second connection electrode CNE2 through a connection contact hole CNT-3 defined by passing through the fifth insulation layer 50. Therefore, the anode AE may be electrically connected to the signal transmission line SCL through the first and second connection electrodes CNE1 and CNE2, and thus electrically connected to a corresponding circuit element.

The anode AE may include a single-layer or multi-layer structure. The anode AE may include a plurality of layers containing ITO and Ag. For example, the anode AE may include an ITO-containing layer (hereinafter, lower ITO layer), an Ag-containing layer disposed on the lower ITO layer (hereinafter, Ag layer), and an ITO-containing layer disposed on the Ag layer (hereinafter, upper ITO layer).

The sacrificial pattern SP may be disposed between the anode AE and the pixel-defining film PDL. A sacrificial opening OP-S defined by portions of the sacrificial pattern SP which exposes a portion of an upper surface of the anode AE to outside the sacrificial pattern SP may be defined in the sacrificial pattern SP. The sacrificial opening OP-S may overlap a light-emitting opening OP-E of the pixel-defining layer, to be described later.

The pixel-defining film PDL may be disposed on the fifth insulation layer 50 of the circuit element layer DP-CL. The light-emitting opening OP-E may be defined in (or by) the pixel-defining film PDL. The light-emitting opening OP-E may correspond to the anode AE, and the pixel-defining film PDL may expose at least a portion of the anode AE to outside the pixel-defining film PDL, through the light-emitting opening OP-E.

In addition, the light-emitting opening OP-E may correspond to the sacrificial opening OP-S of the sacrificial pattern SP. According to this embodiment, the upper surface of the anode AE may be spaced apart from the pixel-defining film PDL with the sacrificial pattern SP therebetween on a cross-section and along the third direction DR3. Accordingly, protections of the anode AE from being damaged in a process of forming the light-emitting opening OP-E may be possible.

On a plane, the area of the light-emitting opening OP-E may be smaller than the area of the sacrificial opening OP-S. That is, an inner side surface of the pixel-defining film PDL which defines the light-emitting opening OP-E, may be more adjacent to (e.g., closer to) the center of the anode AE than an inner side surface of the sacrificial pattern SP which defines the sacrificial opening OP-S. However, an embodiment of the invention is not limited thereto, and the inner side surface of the sacrificial pattern SP defining the sacrificial opening OP-S may also be substantially aligned with the inner side surface of the pixel-defining film PDL defining the light-emitting opening OP-E. At this time, the light-emitting region PXA may also be regarded as a region of the anode AE which is exposed by a corresponding sacrificial pattern opening OP-S.

The pixel-defining film PDL may include an inorganic insulating material. For example, the pixel-defining film PDL may include silicon nitride (SiNx). The pixel-defining film PDL may be disposed between the anode AE and the partition wall PW, and may thus prevent the anode AE and the partition wall PW from being electrically connected to each other.

The light-emitting pattern EP may be disposed on the anode AE. The light-emitting pattern EP may include a light-emitting layer containing a light-emitting material. The light-emitting pattern EP may further include a hole injection layer (HIL) and a hole transport layer (HTL) which are disposed between the anode AE and the light-emitting layer, and may further include an electron transport layer (ETL) and an electron injection layer (EIL) disposed on the light-emitting layer. The light-emitting pattern EP may also be referred to as an ‘organic layer’ or an ‘intermediate layer’.

The light-emitting pattern EP may have a discrete shape. The discrete shape may be provided by a material layer of the light-emitting pattern EP being disconnected by the stacked structure on which such material layer is applied. In an embodiment of providing the display panel DP, the material providing the light-emitting pattern EP may be patterned (or disconnected) by a tip portion defined by an inner sidewall of the partition wall PW, where a disconnected portion provides the light-emitting pattern EP within a respective opening at the light-emitting region PXA. The light-emitting pattern EP may be disposed inside the sacrificial pattern opening OP-S at the sacrificial pattern layer, inside the light-emitting opening OP-E at the pixel-defining layer, and inside a partition wall opening OP-P at the bank layer. The aforementioned openings may together form a light-emission opening at the light-emitting region PXA. The light-emitting pattern EP may extend from the anode AE to cover a portion of an upper surface of the pixel-defining film PDL exposed at the light-emission opening by the partition wall opening OP-P.

The cathode CE may be disposed on the light-emitting pattern EP. Similar to that described above, a material providing the cathode CE may be patterned by the tip portion defined by the partition wall PW. At least a portion of the cathode CE may be disposed in the partition wall opening OP-P. The cathode CE may be in contact with a first inner side surface S-L1 of a first partition wall layer L1, where the first inner side surface S-L1 defines a lower portion of the bank opening. The cathode CE may have conductivity. The cathode CE may be formed of various materials as long as having conductivity such as metal, transparent conductive oxide (TCO), or a conductive polymer material. For example, the cathode CE may include silver (Ag), magnesium (Mg), lead (Pb), copper (Cu), or a compound thereof.

According to an embodiment of the invention, the display element layer DP-OLED may further include a capping pattern (not shown). The capping pattern may be disposed in the partition wall opening OP-P, and disposed on the cathode CE. Here, a material layer providing the capping pattern may be patterned by the tip portion formed by the partition wall PW.

The partition wall PW may be disposed on the pixel-defining film PDL. The partition wall opening OP-P may be defined in the partition wall PW, by solid portions thereof. The partition wall opening OP-P may correspond to the light-emitting opening OP-E defined by solid portions of the pixel-defining layer, and may expose at least a portion of the anode AE to outside the bank layer.

The partition wall PW may have an undercut shape on a cross-section. The partition wall PW may include multiple layers stacked in sequence, and at least one layer, among the multiple layers, may be recessed compared to another layer, such as to form an undercut structure. Accordingly, the partition wall PW may include or define the tip portion.

The partition wall PW may include a first partition wall layer L1 and a second partition wall layer L2. The first partition wall layer L1 may be disposed on the pixel-defining film PDL, and the second partition wall layer L2 may be disposed on the first partition wall layer L1. As illustrated in FIG. 6, the thickness of the first partition wall layer L1 may be larger than the thickness of the second partition wall layer L2, but an embodiment of the invention is not limited thereto.

The first partition wall layer L1 may be relatively recessed, compared to the second partition wall layer L2, at the light-emitting region PXA. The first partition wall layer L1 may be formed by recessing a sidewall of the first partition wall layer L1 relative to a sidewall of the second partition wall layer L2. A portion of the second partition wall layer L2, protruding further than the sidewall of the first partition wall layer L1 toward the light-emitting region PXA, may be defined as the tip portion of the partition wall PW.

The partition wall opening OP-P defined in the partition wall PW may include a first region A1 as a first thickness portion (or upper volume portion) and a second region A2 as a second thickness portion (or lower volume portion). The first partition wall layer L1 may include a first inner side surface S-L1 at which the first region A1 of the partition wall opening OP-P is defined, and the second partition wall layer L2 may include a second inner side surface S-L2 at which the second region A2 is defined.

On a cross-section, the second inner side surface S-L2 of the second partition wall layer L2 may be more adjacent to the center of the anode AE than the first inner side surface S-L1 of the first partition wall layer L1, owing to the undercut structure of the bank layer which is at a light-emitting region PXA. The first inner side surface S-L1 may be recessed in a direction away from the center of the anode AE, relative to the second inner side surface S-L2. Accordingly, the second partition wall layer L2, protruding toward the light-emitting region PXA, may include or define the tip portion.

In a direction along the circuit element layer DP-CL, such as along the first direction DR1 and/or the second direction DR2, the width of the first region A1 may be different from the width of the second region A2. The width of the first region A1 may be larger than the width of the second region A2. In this case, the second region A2 of the partition wall opening OP-P may be a region defining the tip portion.

The first partition wall layer L1 and the second partition wall layer L2 may each include a conductive material. For example, the conductive material may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy thereof. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

FIG. 6 exemplarily illustrates that the first inner side surface S-L1 and the second inner side surface S-L2 may each be perpendicular to the upper surface of the pixel-defining film PDL, but an embodiment of the invention is not limited thereto. For example, the partition wall PW may have a tapered shape, or have a reversed tapered shape, where an inner side surface may be inclined with respect to the upper surface of the pixel-defining layer.

The partition wall PW may receive the second driving voltage ELVSS (see FIG. 3), and accordingly, the cathode CE may be electrically connected to the partition wall PW to receive the second driving voltage ELVSS (see FIG. 3).

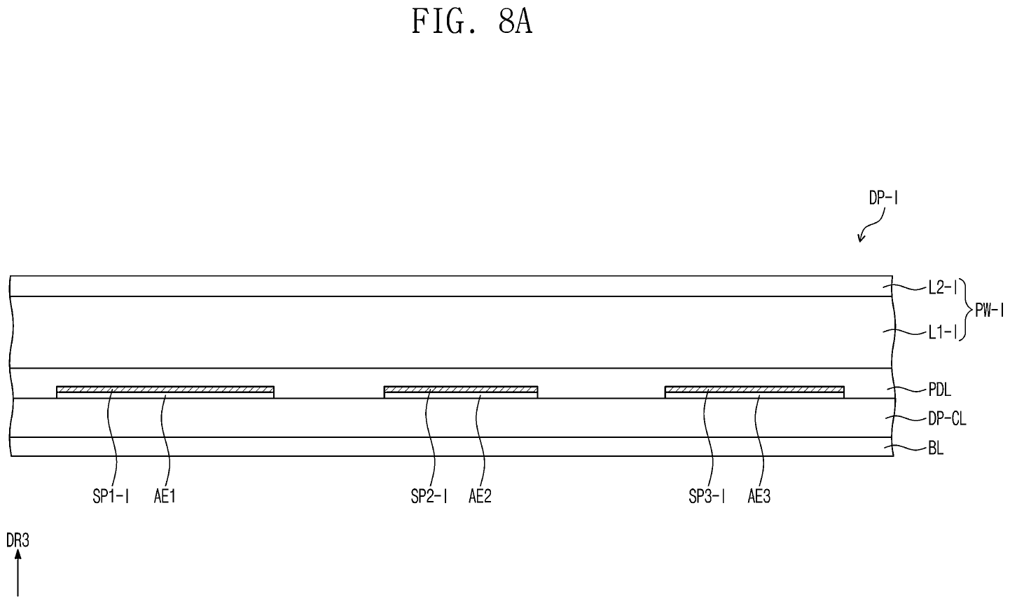

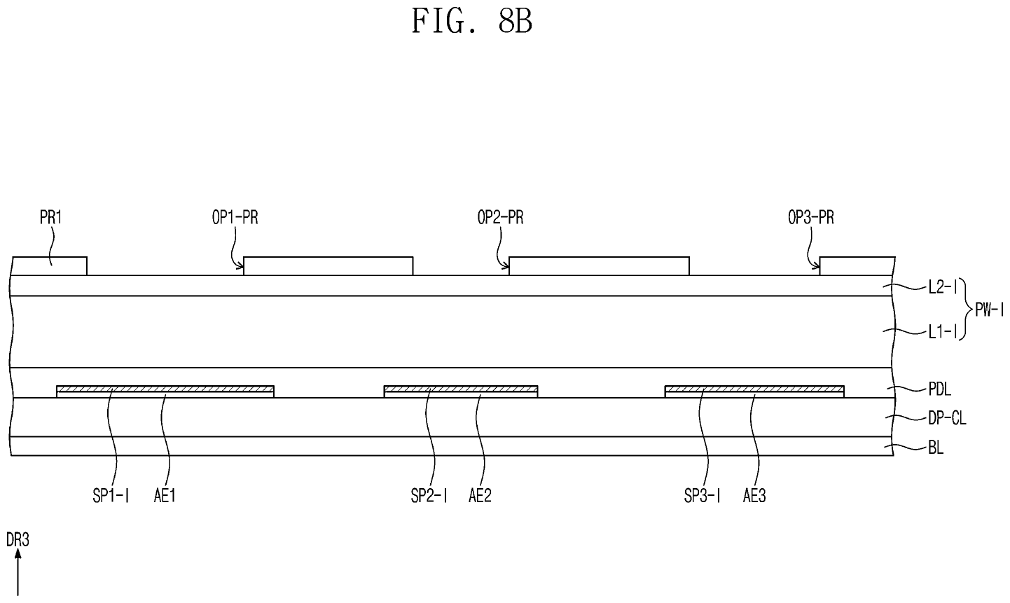

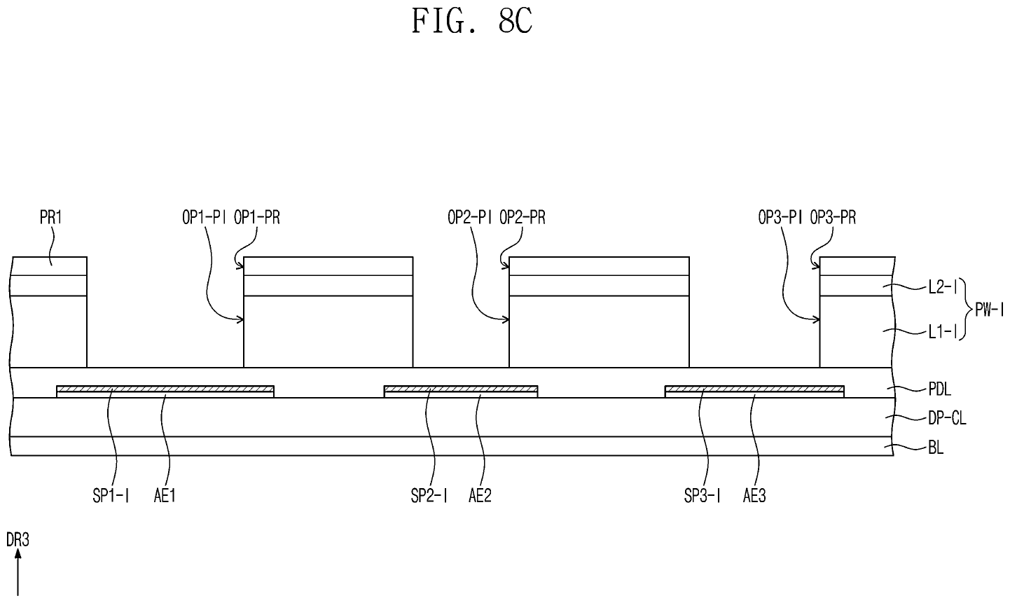

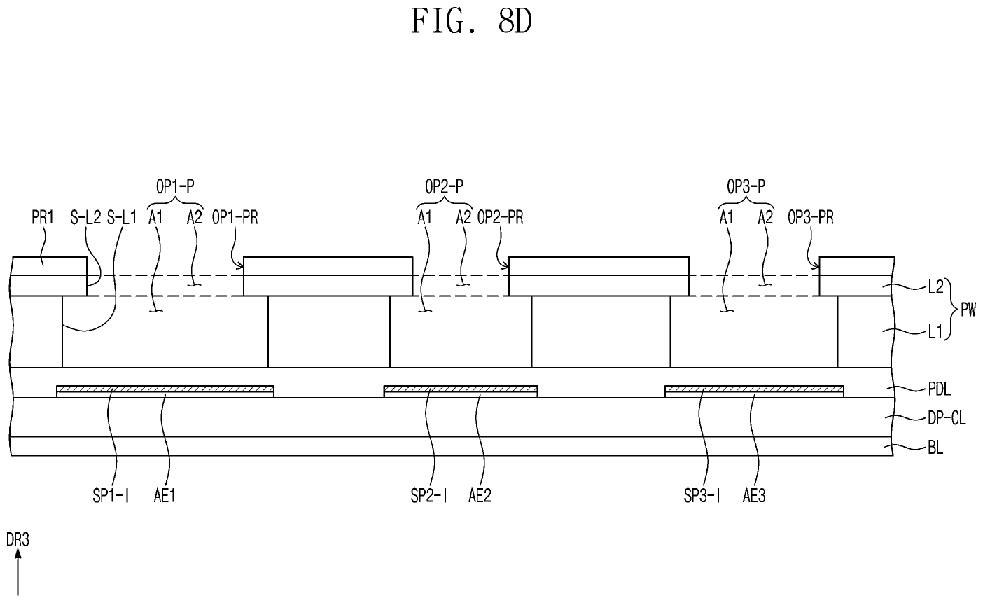

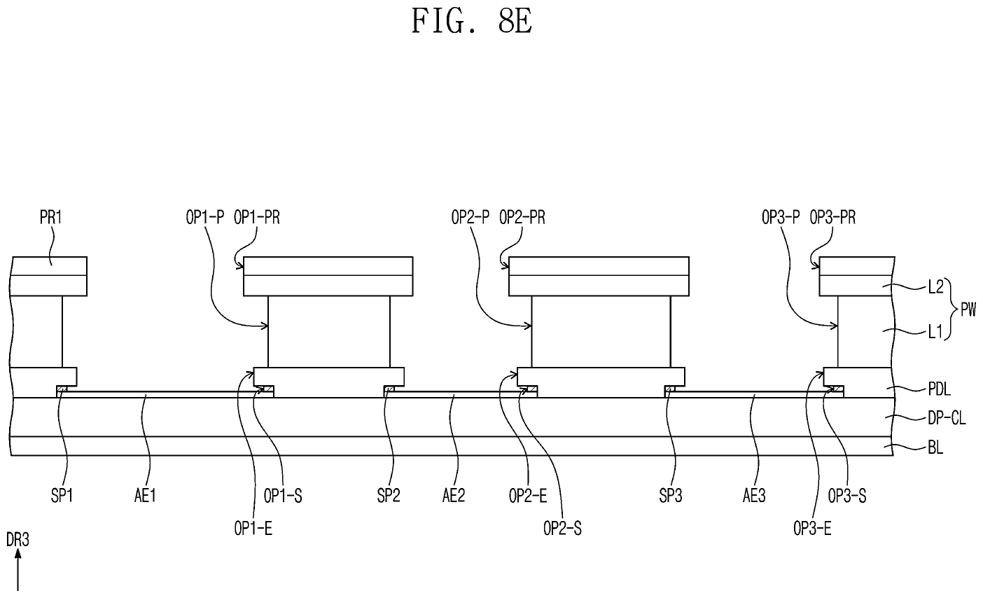

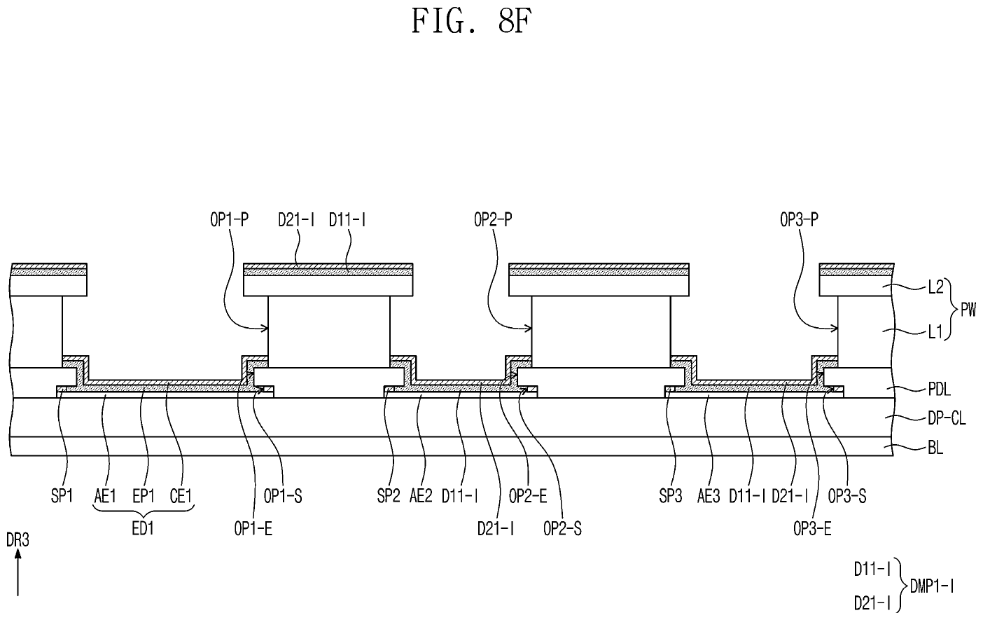

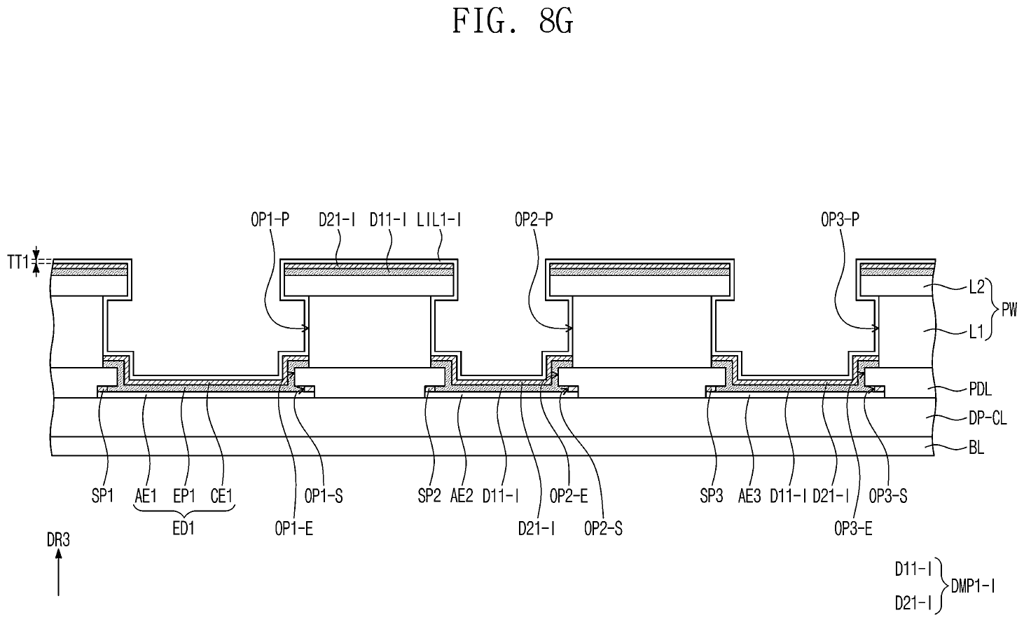

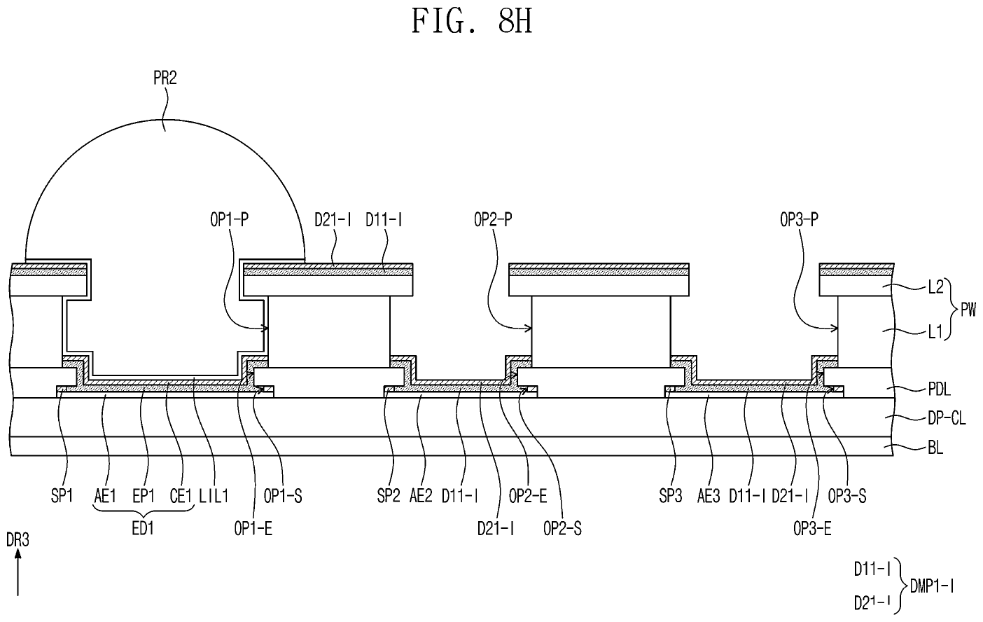

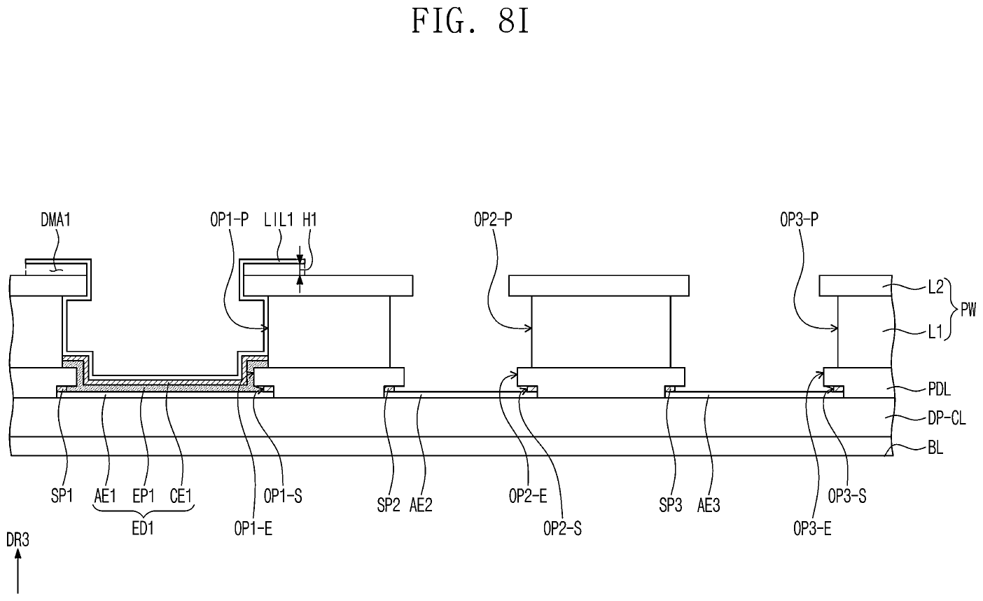

A dummy region DMA may be formed on the partition wall PW. In particular, the dummy region DMA may be formed between the partition wall PW and a lower inorganic encapsulation pattern LIL on a cross-section. The dummy region DMA may be defined as a region where first to third dummy layers DMP1-I, DMP2-I, and DMP3-I (see FIG. 8F, 9A, or 10A) are formed and removed during a method of providing a display panel DP to be described later.

The thin-film encapsulation layer TFE may be disposed on the display element layer DP-OLED. The thin-film encapsulation layer TFE as an encapsulation layer may include a lower inorganic encapsulation pattern LIL, an organic encapsulation film OL, and an upper inorganic encapsulation film UIL.

The lower inorganic encapsulation pattern LIL may correspond to the light-emitting opening OP-E. The lower inorganic encapsulation pattern LIL may be disposed on the cathode CE. In particular, a portion of the lower inorganic encapsulation pattern LIL may be formed in the partition wall opening OP-P, and another portion of the lower inorganic encapsulation pattern LIL may be formed on the partition wall PW. That is, the lower inorganic encapsulation pattern LIL in the partition wall opening OP-P may extend out of the partition wall opening OP-P and along an upper surface of the partition wall PW.

The organic encapsulation film OL may cover the lower inorganic encapsulation pattern LIL, and provide a flat upper surface. A portion of the organic encapsulation film OL may extend into a gap between the upper surface of the partition wall PW and a lower surface of the lower inorganic encapsulation pattern LIL which is spaced apart from the partition wall PW, to fill the dummy region DMA. The upper inorganic encapsulation film UIL may be disposed on the organic encapsulation film OL.

The lower inorganic encapsulation pattern LIL and the upper inorganic encapsulation film UIL may protect the display element layer DP-OLED from moisture/oxygen, and the organic encapsulation film OL may protect the display element layer DP-OLED from foreign substances such as dust particles.

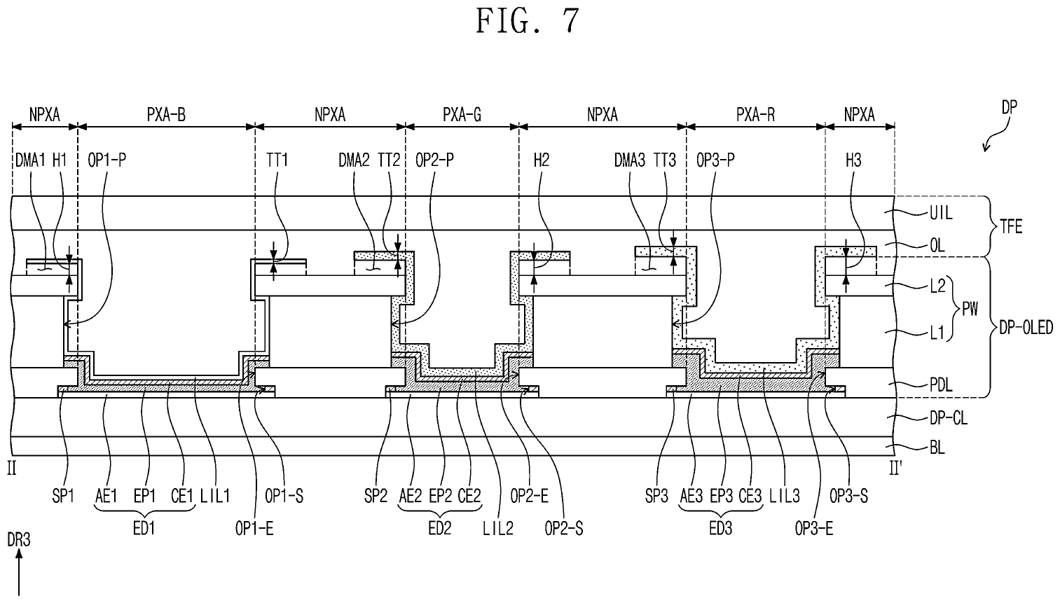

FIG. 7 is a cross-sectional view taken along line II-II′ of FIG. 5. FIG. 7 is an enlarged view illustrating one first light-emitting region PXA-B, one second light-emitting region PXA-G, and one third light-emitting region PXA-R, and the description of the light-emitting region PXA with reference to FIG. 6 may be equally applied to each of the first to third light-emitting regions PXA-B, PXA-G, and PXA-R in FIG. 7.

Referring to FIG. 7, a display panel DP may include a base layer BL, a circuit element layer DP-CL, a display element layer DP-OLED, and a thin-film encapsulation layer TFE. The display element layer DP-OLED may include light-emitting elements ED1, ED2, and ED3, sacrificial patterns SP1, SP2, and SP3, a pixel-defining film PDL, and a partition wall PW.

The light-emitting elements ED1, ED2, and ED3 may include a first light-emitting element ED1, a second light-emitting element ED2, and a third light-emitting element ED3. The first light-emitting element ED1 may include a first anode AE L1, a first light-emitting pattern EP1, and a first cathode CE1. The second light-emitting element ED2 may include a second anode AE2, a second light-emitting pattern EP2, and a second cathode CE2. The third light-emitting element ED3 may include a third anode AE3, a third light-emitting pattern EP3, and a third cathode CE3. The first to third anodes AE1, AE2, and AE3 may be provided in a plurality of patterns. In an embodiment, the first light-emitting pattern EP1 may provide blue light, the second light-emitting pattern EP2 may provide green light, and the third light-emitting pattern EP3 may provide red light.

First to third light-emitting openings OP1-E, OP2-E, and OP3-E may be defined in the pixel-defining film PDL. The first light-emitting opening OP1-E may expose at least a portion of the first anode AE1. The second light-emitting opening OP2-E may expose at least a portion of the second anode AE2. The third light-emitting opening OP3-E may expose at least a portion of the third anode AE3.

In this embodiment, the first light-emitting region PXA-B may be defined as a region of an upper surface of the first anode AE1 exposed by the first light-emitting opening OP1-E. The second light-emitting region PXA-G may be defined as a region of an upper surface of the second anode AE2 exposed by the second light-emitting opening OP2-E. The third light-emitting region PXA-R may be defined as a region of an upper surface of the third anode AE3 exposed by the third light-emitting opening OP3-E.

The sacrificial patterns SP1, SP2, and SP3 may include a first sacrificial pattern SP1, a second sacrificial pattern SP2, and a third sacrificial pattern SP3. The first to third sacrificial patterns SP1, SP2, and SP3 may be respectively disposed on the upper surfaces of the first to third anodes AE1, AE2, and AE3. First to third sacrificial pattern openings OP1-S, OP2-S, and OP3-S, respectively overlapping the first to third light-emitting openings OP1-E, OP2-E, and OP3-E, may be defined in the first to third sacrificial patterns SP1, SP2, and SP3.

In this embodiment, first to third partition wall openings OP1-P, OP2-P, and OP3-P, respectively overlapping the first to third light-emitting openings OP1-E, OP2-E, and OP3-E, may be defined in the partition wall PW. The first to third partition wall openings OP1-P, OP2-P, and OP3-P may each include the first region A1 (see FIG. 6) and the second region A2 (see FIG. 6) previously described with reference to FIG. 6. A first partition wall layer L1 may include the first inner side surfaces S-L1 (see FIG. 6) defining the first regions A1 of the first to third partition wall openings OP1-P, OP2-P, and OP3-P, and a second partition wall layer L2 may include the second inner side surfaces S-L2 (see FIG. 6) defining the second regions A2 of the first to third partition wall openings OP1-P, OP2-P, and OP3-P.

The first light-emitting pattern EP1 and the first cathode CE1 may be disposed in the first partition wall opening OP1-P, the second light-emitting pattern EP2 and the second cathode CE2 may be disposed in the second partition wall opening OP2-P, and the third light-emitting pattern EP3 and the third cathode CE3 may be disposed in the third partition wall opening OP3-P.

In this embodiment, a material layer of the first to third light-emitting patterns EP1, EP2, and EP3 and the material layer of the first to third cathodes CE1, CE2, and CE3 may be respectively physically separated by the second partition wall layer L2 which forms the tip portion, such that the first to third light-emitting patterns EP1, EP2, and EP3 and the first to third cathodes CE1, CE2, and CE3 may be respectively formed as patterns in the light-emitting openings OP1-E, OP2-E, and OP3-E, or in the partition wall openings OP1-P, OP2-P, and OP3-P.

According to an embodiment of the invention, a plurality of first light-emitting patterns EP1 may be deposited through patterning on a pixel-by-pixel basis, by the tip portion defined on the partition wall PW which disconnects a light-emitting material layer forming light-emitting patterns. That is, the first light-emitting patterns EP1 may be formed in common as a single material layer using an open mask, but may be easily divided into pixels by the partition wall PW.

On the other hand, in case of patterning the first light-emitting patterns EP1 using a fine metal mask (FMM), a supporting spacer, protruding from a conventional conductive partition wall, may be provided in order to support the fine metal mask. In addition, since the fine metal mask is spaced apart, by the height of the conventional partition wall and the spacer, from a base surface on which the patterning is performed, there may be a limitation in achieving high resolution of the formed patterns. In addition, since the fine metal mask is in contact with the spacer, foreign substances may remain on the spacer after the patterning process of the first light-emitting patterns EP1, or the spacer may be damaged due to stamping of the fine metal mask. Accordingly, a conventional display panel may be formed with defects.

According to this embodiment of the invention, as the partition wall PW is included, a respective material layer of the light-emitting elements ED1, ED2, and ED3 may be physically separated with ease. Accordingly, leakage current, driving errors, or the like, which may occur between the adjacent light-emitting regions PXA-B, PXA-G, and PXA-R, may be reduced or effectively prevented, and independent operation of each of the light-emitting elements ED1, ED2, and ED3 may be possible.

In particular, since the plurality of first light-emitting patterns EP1 are patterned without a mask in contact with components inside the display region DA (see FIG. 1B), the defect rate may be reduced, so that the display panel DP with improved process reliability may be provided. Since the patterning of a material layer may be possible even without providing a separate supporting spacer protruding from the partition wall PW, the areas of the light-emitting regions PXA-B, PXA-G, and PXA-R may be miniaturized, thereby providing the display panel DP which facilitates high-resolution implementation.

In addition, in manufacturing a large-area display panel DP, manufacturing a large-area mask may be omitted, so that the process cost may be reduced, and since defects which might occur on the large-area mask may not affect the process, it may be possible to provide the display panel DP with improved process reliability. The description of the plurality of first light-emitting patterns EP1 may be equally applied to a plurality of second and third light-emitting patterns EP2 and EP3.

The thin-film encapsulation layer TFE may include lower inorganic encapsulation patterns LIL1, LIL2, and LIL3, an organic encapsulation film OL, and an upper inorganic encapsulation film UIL.

In this embodiment, the lower inorganic encapsulation patterns LIL1, LIL2, and LIL3 may include a first lower inorganic encapsulation pattern LIL1, a second lower inorganic encapsulation pattern LIL2, and a third lower inorganic encapsulation pattern LIL3. The first to third lower inorganic encapsulation patterns LIL1, LIL2, and LIL3 may respectively overlap the first to third light-emitting openings OP1-E, OP2-E, and OP3-E. The first to third lower inorganic encapsulation patterns LIL1, LIL2, and LIL3 may be provided in the form of patterns spaced apart from each other.

The first lower inorganic encapsulation pattern LIL may cover the first light-emitting element ED1. A portion of the first lower inorganic encapsulation pattern LIL1 may be formed in the first partition wall opening OP1-P, and another portion of the first lower inorganic encapsulation pattern LIL1 may be formed on an upper surface of the partition wall PW which extends from a sidewall thereof defining the first partition wall opening OP1-P. On a cross-section, a first dummy region DMA1 may be formed as a first gap between the first lower inorganic encapsulation pattern LIL1 and the partition wall PW which defines the first partition wall opening OP1-P.

The second lower inorganic encapsulation pattern LIL2 may cover the second light-emitting element ED2. A portion of the second lower inorganic encapsulation pattern LIL2 may be formed in the second partition wall opening OP2-P, and another portion of the second lower inorganic encapsulation pattern LIL2 may be formed on an upper surface of the partition wall PW which extends from a sidewall thereof defining the second partition wall opening OP2-P. On a cross-section, a second dummy region DMA2 may be formed as a second gap between the second lower inorganic encapsulation pattern LIL2 and the partition wall PW which defines the second partition wall opening OP2-P.

The third lower inorganic encapsulation pattern LIL3 may cover the third light-emitting element ED3. A portion of the third lower inorganic encapsulation pattern LIL3 may be formed in the third partition wall opening OP3-P, and another portion of the third lower inorganic encapsulation pattern LIL3 may be formed on an upper surface of the partition wall PW which extends from a sidewall thereof defining the third partition wall opening OP3-P. On a cross-section, a third dummy region DMA3 may be formed as a third gap between the third lower inorganic encapsulation pattern LIL3 and the partition wall PW which defines the third partition wall opening OP3-P.

The first to third lower inorganic encapsulation patterns LIL1, LIL2, and LIL3 may differ from each other in thickness. A thickness of a respective lower inorganic encapsulation pattern may be defined in a direction normal to a surface along which the respective lower encapsulation pattern is defined. Referring to FIG. 7, for example, thicknesses may not only be defined along the third direction DR3, but may be defined along a horizontal direction (e.g., the first direction DR1 and/or the second direction DR2).

A thickness TT1 of the first lower inorganic encapsulation pattern LIL1 may be smaller than a thickness TT2 of the second lower inorganic encapsulation pattern LIL2, and a thickness TT3 of the third lower inorganic encapsulation pattern LIL3 may be equal to or greater than the thickness TT2 of the second lower inorganic encapsulation pattern LIL2. For example, the thickness TT1 of the first lower inorganic encapsulation pattern LIL1 may be about 0.2 micrometer (μm) to about 1.0 μm, the thickness TT2 of the second lower inorganic encapsulation pattern LIL2 may be about 1.0 μm to about 1.5 micrometers (μm), and the thickness TT3 of the third lower inorganic encapsulation pattern LIL3 may be about 1.0 μm to about 1.7 μm.

A height of the gap at a respective dummy region may be defined along the third direction DR3. The respective height may be a minimal distance between facing surfaces. The facing surfaces may be defined by an upper surface of the partition wall PW at the second partition wall layer L2 and a lower surface of the lower inorganic encapsulation pattern LIL at an extended portion thereof. The extended portion of the lower inorganic encapsulation pattern LIL of a respective light-emitting region may extend from such light-emitting region and in a direction towards an adjacent light-emitting region. By the extended portion being spaced apart from the uppermost surface of the partition wall PW, the gap is open in a direction away from the respective light-emitting region.

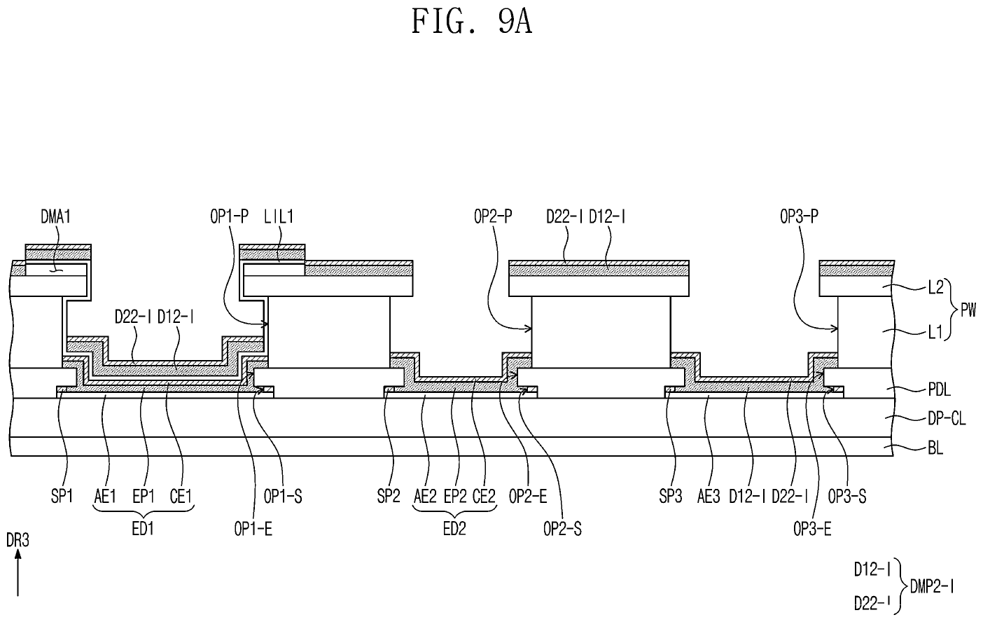

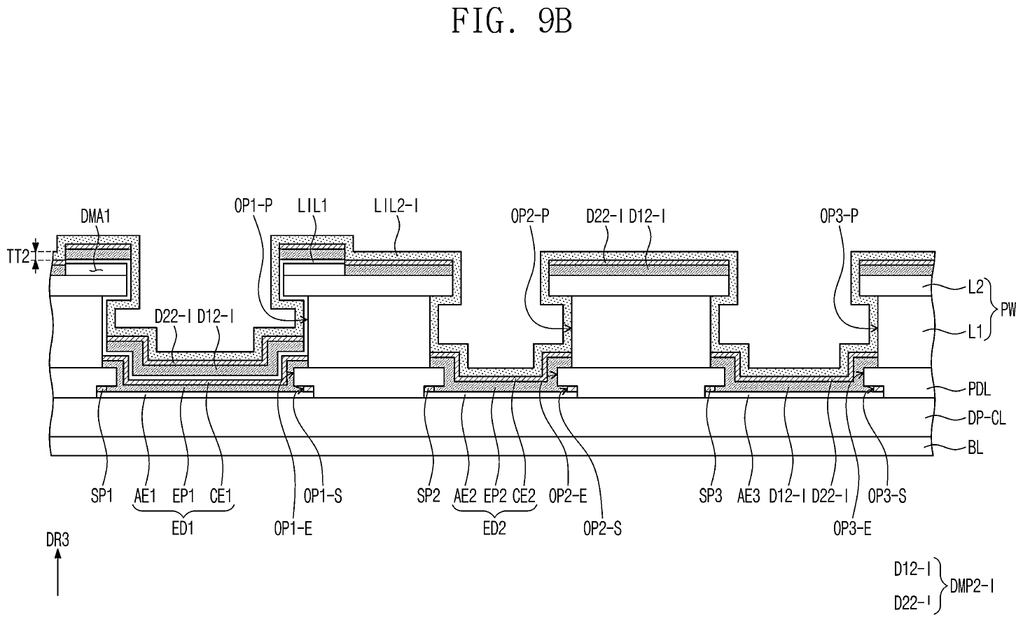

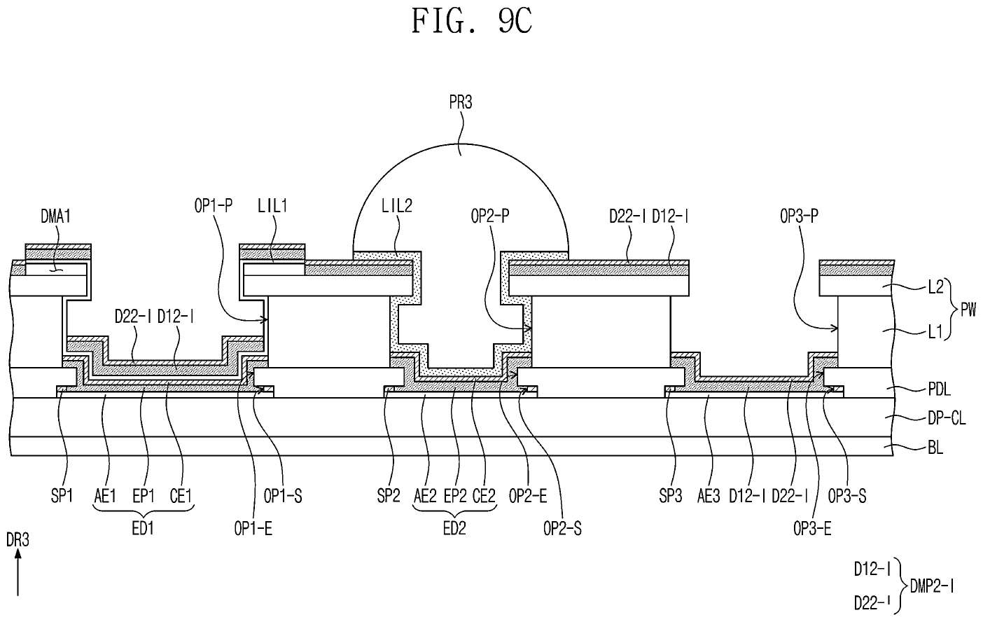

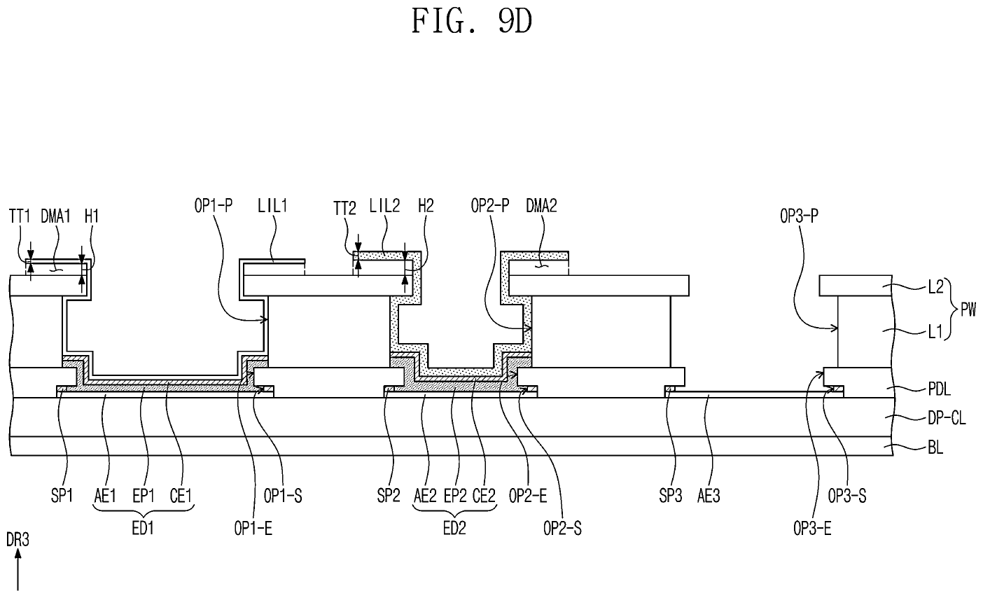

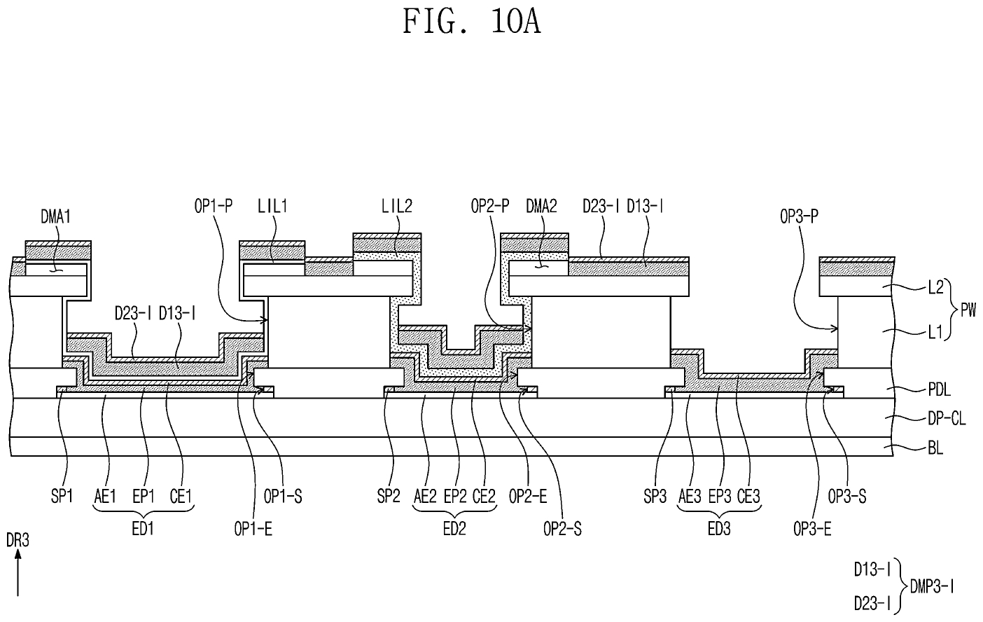

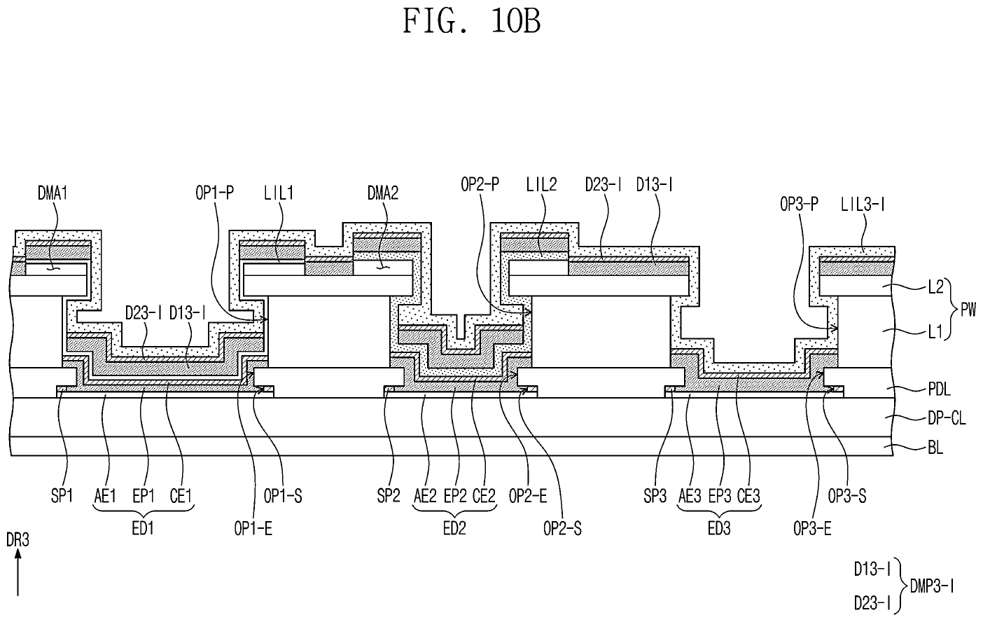

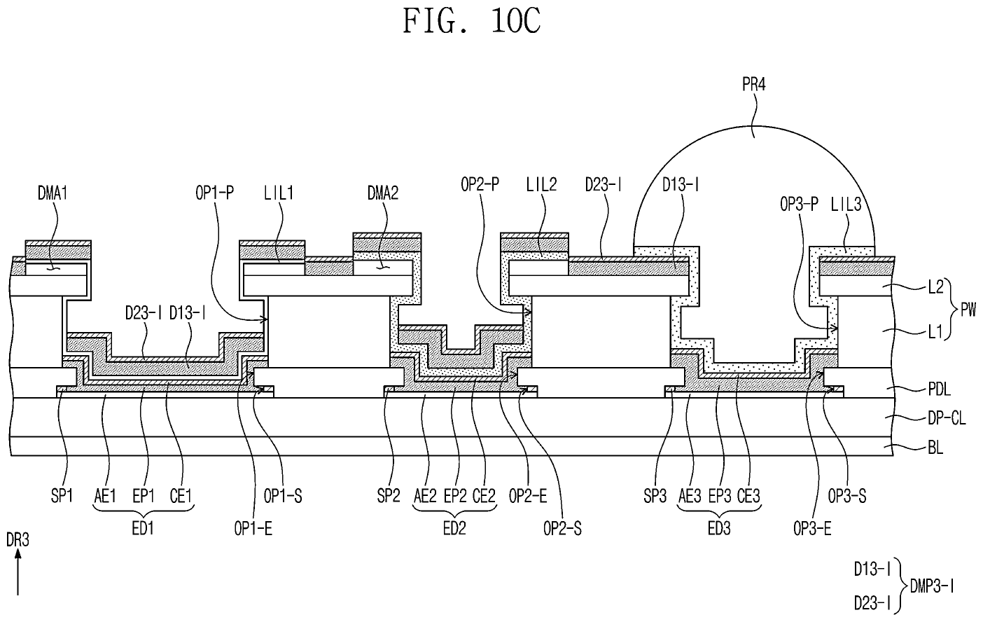

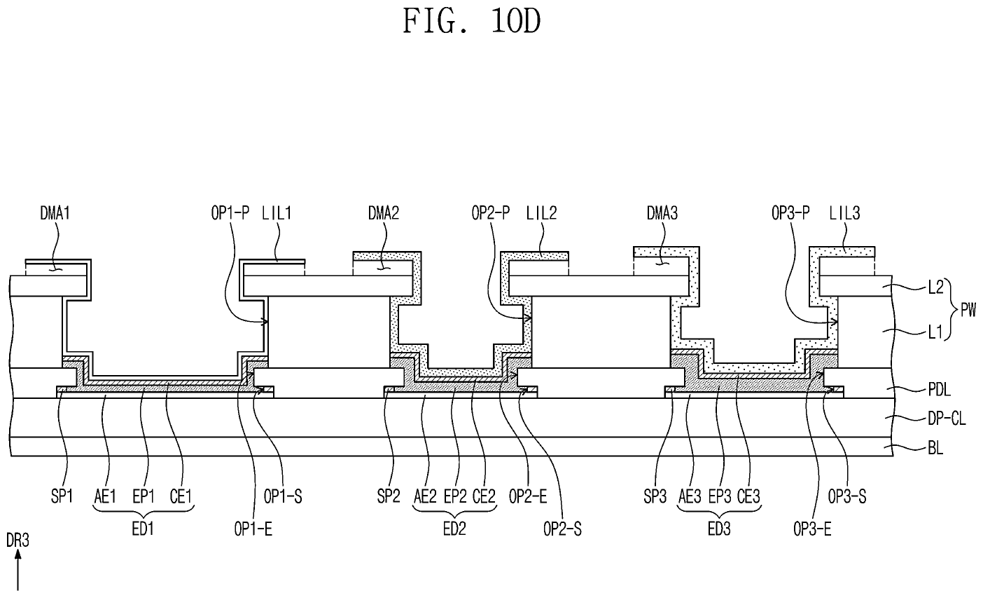

A height H1 of the first dummy region DMA1 may correspond to the thickness of a first dummy layer DMP1-I (see FIG. 8F) during process of providing a display panel DP to be described later, and the thickness of the first dummy layer DMP1-I may correspond to a sum of thicknesses of the first light-emitting pattern EP1 and the first cathode CE1. A height H2 of the second dummy region DMA2 may correspond to the thickness of a second dummy layer DMP2-I (see FIG. 9A) during a process of providing the display panel DP to be described later, and the thickness of the second dummy layer DMP2-I may correspond to a sum of thicknesses of the second light-emitting pattern EP2 and the second cathode CE2. A height H3 of the third dummy region DMA3 may correspond to the thickness of a third dummy layer DMP3-I (see FIG. 10A) during a process of providing the display panel DP to be described later, and the thickness of the third dummy layer DMP3-I may correspond to a sum of thicknesses of the third light-emitting pattern EP3 and the third cathode CE3. That is, the height of a gap adjacent to a respective light-emitting region is directly related to a thickness of the light-emitting pattern in that respective light-emitting region.

The first to third light-emitting patterns EP1, EP2, and EP3 may differ from each other in thickness. Similar to that described above, a thickness of a respective light-emitting pattern may be defined in a direction normal to a surface along which the respective pattern is defined. For example, the thickness of the first light-emitting pattern EP1 may be smaller than the thickness of the second light-emitting pattern EP2, and the thickness of the third light-emitting pattern EP3 may be larger than the thickness of the second light-emitting pattern EP2. Therefore, the respective heights H1, H2, and H3 of the first to third dummy regions DMA1, DMA2, and DMA3 may be different from each other, owing to the different thicknesses of the light-emitting patterns while the thickness of the cathode electrodes may be substantially the same. For example, the height H1 of the first dummy region DMA1 may be smaller than the height H2 of the second dummy region DMA2, and the height H3 of the third dummy region DMA3 may be greater than the height H2 of the second dummy region DMA2.

FIGS. 8A to 11 are cross-sectional views illustrating processes and structure from operations of a method of manufacturing (or providing) a display panel DP according to an embodiment of the invention. In describing with reference to FIGS. 8A to 11, same/similar components to/with the components in FIGS. 1 to 7 will be denoted as the same/similar reference numerals or symbols, and duplicate descriptions thereof will be omitted.

A method of manufacturing (or providing) a display panel DP, according to an embodiment of the invention, may include providing a preliminary display panel DP-I including a base layer BL, a pixel-defining film PDL disposed on the base layer BL, a first preliminary partition wall layer L1-I disposed on the pixel-defining film PDL, and a second preliminary partition wall layer L2-I disposed on the first preliminary partition wall layer L1-I, etching the first preliminary partition wall layer L1-I and the second preliminary partition wall layer L2-I to form a partition wall PW in which a first partition wall opening OP1-P, a second partition wall opening OP2-P, and a third partition wall opening OP3-P are defined, forming a first light-emitting element ED1 in the first partition wall opening OP1-P, forming a first lower inorganic encapsulation pattern LIL1 which covers the first light-emitting element ED1, forming a second light-emitting element ED2 in the second partition wall opening OP2-P, forming a second lower inorganic encapsulation pattern LIL2 which covers the second light-emitting element ED2, forming a third light-emitting element ED3 in the third partition wall opening OP3-P, and forming a third lower inorganic encapsulation pattern LIL3 which covers the third light-emitting element ED3.

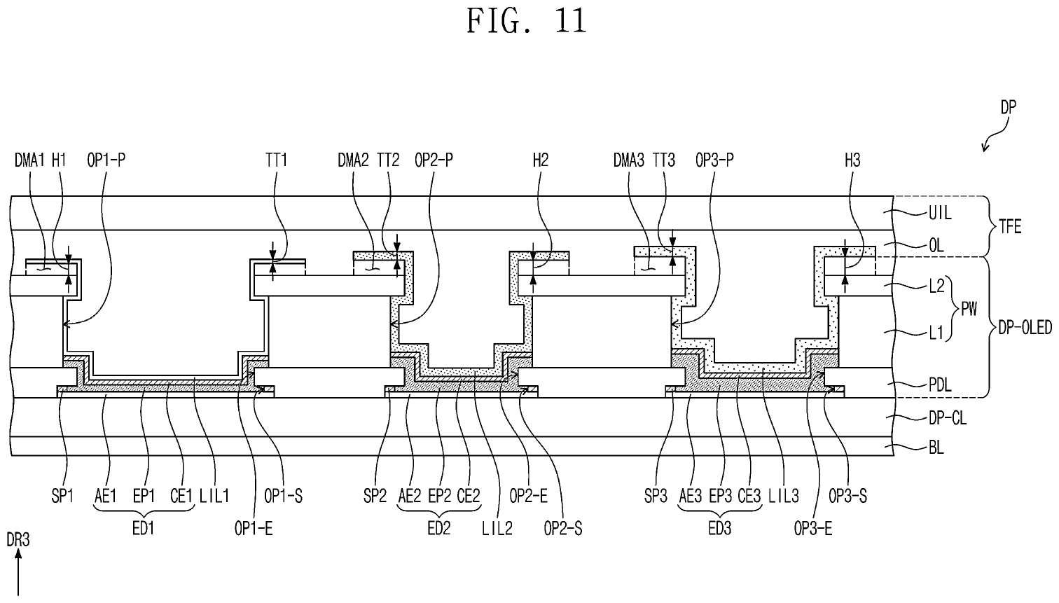

Hereinafter, with reference to FIGS. 8A to 8I, the forming of the first light-emitting element ED1 and the forming of the first lower inorganic encapsulation pattern LIL1 which covers the first light-emitting element ED1 are described, and with reference to FIGS. 9A to 9D, the forming of the second light-emitting element ED2 and the forming of the second lower inorganic encapsulation pattern LIL2 which covers the second light-emitting element ED2 are described. With reference to FIGS. 10A to 10D, the forming of the third light-emitting element ED3 and the forming of the third lower inorganic encapsulation pattern LIL3 which covers the third light-emitting element ED3 are described, and with reference to FIG. 11, forming an organic encapsulation film OL and an upper inorganic encapsulation film UIL are described. A display panel DP, provided (or formed) through operations illustrated in FIGS. 8A to 11, may correspond to the display panel DP in FIG. 7.

Referring to FIG. 8A, the method for providing the display panel DP, according to an embodiment of the invention, may include the providing of the preliminary display panel DP-I. The preliminary display panel DP-I, provided according to this embodiment, may include a base layer BL, a circuit element layer DP-CL, first to third anodes AE1, AE2, and AE3, first to third sacrificial layers SP1-I, SP2-I, and SP3-I, a pixel-defining film PDL, a first preliminary partition wall layer L1-I, and a second preliminary partition wall layer L2-I.

The circuit element layer DP-CL may be formed through a general circuit element manufacturing process in which an insulation layer, a semiconductor layer, and a conductive layer are formed through coating, deposition, etc., and the insulation layer, the semiconductor layer, and the conductive layer are selectively patterned through photolithography and an etching process to thereby form a semiconductor pattern, a conductive pattern, a signal line, and the like.

The first anode AE1 and the first sacrificial layer SP1-I may be formed through the same patterning process, the second anode AE2 and the second sacrificial layer SP2-I may be formed through the same patterning process, and the third anode AE3 and the third sacrificial layer SP3-I may be formed through the same patterning process. Here, ends or end surfaces of corresponding anodes sacrificial layers may be aligned with each other, such as to be coplanar, without being limited thereto.

The pixel-defining film PDL may be disposed on the base layer BL. The pixel-defining film PDL as a pixel-defining layer may cover all of the first to third anodes AE1, AE2, and AE3 and all of the first to third sacrificial layers SP1-I, SP2-I, and SP3-I.

The first preliminary partition wall layer L1-I may be disposed on the pixel-defining film PDL. The first preliminary partition wall layer L1-I may be formed through a deposition process of a conductive material. The second preliminary partition wall layer L2-I may be disposed on the first preliminary partition wall layer L1-I. The second preliminary partition wall layer L2-I may also be formed through a deposition process of a conductive material. In this embodiment, the first preliminary partition wall layer L1-I and the second preliminary partition wall layer L2-I may each include a conductive material. For example, the conductive material may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy thereof. The transparent conductive oxide may include indium tin oxide (ITO), indium zinc oxide (IZO), zinc oxide, indium oxide, indium gallium oxide, indium gallium zinc oxide (IGZO), or aluminum zinc oxide. However, the materials of the first preliminary partition wall layer L1-I and the second preliminary partition wall layer L2-I are not limited thereto. The first preliminary partition wall layer L1-I and the second preliminary partition wall layer L2-I may form a preliminary partition wall PW-I.

Referring to FIG. 8B, the method for providing the display panel DP, according to an embodiment of the invention, may include forming a first photoresist layer PR1 on the preliminary partition wall PW-I. After a preliminary photoresist layer is formed on the preliminary partition wall PW-I, the preliminary photoresist layer is patterned by using a photo mask to thereby form the first photoresist layer PR1. Through the patterning process, a solid portion of the first photoresist layer PR1 has defined therein a first photo opening OP1-PR overlapping the first anode AE1, a second photo opening OP2-PR overlapping the second anode AE2, and a third photo opening OP3-PR overlapping the third anode AE3.

Referring to FIGS. 8C and 8D, the method for providing the display panel DP, according to an embodiment of the invention, may include the etching of the first preliminary partition wall layer L1-I and the second preliminary partition wall layer L2-I using the first photoresist layer PR1 as a mask, to form the partition wall PW in which the first partition wall opening OP1-P, the second partition wall opening OP2-P, and the third partition wall opening OP3-P are defined, so that the partition wall PW may be formed from the preliminary partition wall PW-I (see FIG. 8B). Here, opening portions (e.g., thickness portions) of the partition wall PW may be respectively defined at the first preliminary partition wall layer L1-I and the second preliminary partition wall layer L2-I, and the opening portions corresponding to a respective anode may together form one partition wall opening (or bank opening).

As illustrated in FIG. 8C, performing a first-etching on the first preliminary partition wall layer L1-I and the second preliminary partition wall layer L2-I may include using the first photoresist layer PR1 as a mask and performing a dry etching on the first preliminary partition wall layer L1-I and the second preliminary partition wall layer L2-I to form preliminary partition wall openings OP1-PI, OP2-PI, and OP3-PI in the preliminary partition wall PW-I. The preliminary partition wall openings OP1-PI, OP2-PI, and OP3-PI may include a first preliminary partition wall opening OP1-PI, a second preliminary partition wall opening OP2-PI, and a third preliminary partition wall opening OP3-PI. The first preliminary partition wall opening OP1-PI may be formed overlapping the first anode AE1, the second preliminary partition wall opening OP2-PI may be formed overlapping the second anode AE2, and the third preliminary partition wall opening OP3-PI may be formed overlapping the third anode AE3.

The first dry-etching process according to this embodiment may be performed in an etching condition where the etch selectivity between the first preliminary partition wall layer L1-I and the second preliminary partition wall layer L2-I is substantially the same. Accordingly, an inner side surface of the first preliminary partition wall layer L1-I and a corresponding inner side surface of the second preliminary partition wall layer L2-I, which respectively define the preliminary partition wall openings OP1-PI, OP2-PI, and OP3-PI, may be substantially aligned. As being aligned, the inner side surfaces may be coplanar with each other.

As illustrated in FIG. 8D, performing a second-etching on the first preliminary partition wall layer L1-I (see FIG. 8C) may include using the first photoresist layer PR1 as a mask and performing a wet etching on the first preliminary partition wall layer L1-I at the various preliminary partition wall openings to respectively form partition wall openings OP1-P, OP2-P, and OP3-P from the preliminary partition wall openings OP1-PI, OP2-PI, and OP3-PI (see FIG. 8C). The partition wall openings OP1-P, OP2-P, and OP3-P may include a first partition wall opening OP1-P, a second partition wall opening OP2-P, and a third partition wall opening OP3-P. The first partition wall opening OP1-P may be formed overlapping the first anode AE1, the second partition wall opening OP2-P may be formed overlapping the second anode AE2, and the third partition wall opening OP3-P may be formed overlapping the third anode AE3.

The partition wall openings OP1-P, OP2-P, and OP3-P may each include a first region A1 (e.g., a lower volume) and a second region A2 (e.g., an upper volume) which are formed in sequence in a thickness direction (that is, the third direction DR3). A first partition wall layer L1 may include a first inner side surface S-L1 defining the first region A1 of each of the partition wall openings OP1-P, OP2-P, and OP3-P, and a second partition wall layer L2 may include a second inner side surface S-L2 defining the second region A2.

The second wet-etching process according to this embodiment may be performed in a condition where the etch selectivity between the first preliminary partition wall layer L1-I and the second preliminary partition wall layer L2-I is large. Accordingly, an inner side surface of the partition wall PW which defines the partition wall openings OP1-P, OP2-P, and OP3-P may have an undercut shape on a cross-section. In particular, since the etch rate of the first partition wall layer L1 is larger than the etch rate of the second partition wall layer L2 for an etching solution, the first partition wall layer L1 may be mainly etched more than the second partition wall layer L2. Accordingly, the first inner side surface S-L1 of the first partition wall layer L1 may be recessed inward from the second inner side surface S-L2 of the second partition wall layer L2 to provide an undercut structure. A tip portion of the partition wall PW may be formed by a portion of the second partition wall layer L2 which protrudes further than the first partition wall layer L1.

At the partition wall openings OP1-P, OP2-P, and OP3-P of the partition wall PW having the undercut shape, the pixel-defining film PDL is exposed to outside the partition wall PW.

Referring to FIG. 8E, the method for providing the display panel DP, according to an embodiment of the invention, may include etching the pixel-defining film PDL which is exposed at the partition wall openings OP1-P, OP2-P, and OP3-P and etching the first to third sacrificial layers SP1-I, SP2-I, and SP3-I (see FIG. 8D) which are subsequently exposed at the partition wall openings OP1-P, OP2-P, and OP3-P after the etching of the pixel-defining film PDL. The etching process of the pixel-defining film PDL may be performed in dry etching using the first photoresist layer PR1 and the partition wall PW (for example, second partition wall layer L2) as a mask. First to third light-emitting openings OP1-E, OP2-E, and OP3-E, respectively corresponding to the first to third partition wall openings OP1-P, OP2-P, and OP3-P, may be formed in the pixel-defining film PDL by sidewalls or inner surfaces thereof.

The first light-emitting opening OP1-E may overlap the first partition wall opening OP1-P, the second light-emitting opening OP2-E may overlap the second partition wall opening OP2-P, and the third light-emitting opening OP3-E may overlap the third partition wall opening OP3-P.

The etching process of the sacrificial layers SP1-I, SP2-I, and SP3-I may be performed in wet etching using the first photoresist layer PR1 and the partition wall PW (for example, second partition wall layer L2) as a mask. Sacrificial pattern openings OP1-S, OP2-S, and OP3-S, respectively overlapping the light-emitting openings OP1-E, OP2-E, and OP3-E, may be respectively formed in sacrificial patterns SP1, SP2, and SP3 formed by the etching of the sacrificial layers SP1-I, SP2-I, and SP3-I. The sacrificial pattern openings OP1-S, OP2-S, and OP3-S may include a first sacrificial pattern opening OP1-S overlapping the first light-emitting opening OP1-E, a second sacrificial pattern opening OP2-S overlapping the second light-emitting opening OP2-E, and a third sacrificial pattern opening OP3-S overlapping the third light-emitting opening OP3-E. At least portions of the anodes AE1, AE2, and AE3 may be exposed to outside the sacrificial patterns SP1, SP2, and SP3, respectively, and to outside the pixel-defining film PDL by the sacrificial pattern openings OP1-S. OP2-S, and OP3-S, and to outside the partition wall PW by the light-emitting openings OP1-E, OP2-E, and OP3-E.

The etching process of the sacrificial patterns SP1, SP2, and SP3 may be performed in a condition where the etch selectivity between the sacrificial patterns SP1, SP2, and SP3 and the anodes AE1, AE2, and AE3 is large, thereby preventing the anodes AE1, AE2, and AE3 from being etched together with etching of the preliminary sacrificial layers SP1-I, SP2-I, and SP3-I. That is, since the sacrificial patterns SP1, SP2, and SP3, having higher etch rates than the anodes AE1, AE2, and AE3, are disposed between the pixel-defining film PDL and the anodes AE1, AE2, and AE3, the anodes AE1, AE2, and AE3 may be prevented from being etched together and damaged during the etching process.

Referring to FIG. 8F, the method for providing the display panel DP, according to an embodiment of the invention, may include the forming of the first light-emitting element ED1 in the first partition wall opening OP1-P after removing the first photoresist layer PR1 (see FIG. 8E). The forming of the first light-emitting element ED1 in the first partition wall opening OP1-P may include forming a first light-emitting pattern EP1 and forming a first cathode CE1. In addition, the forming of the first light-emitting element ED1 in the first partition wall opening OP1-P may include forming a first dummy layer DMP1-I inside the second and third partition wall openings OP2-P and OP3-P and on the partition wall PW.

The forming of the first light-emitting pattern EP1 may include a deposition process of a first light-emitting layer. In an embodiment, the deposition process of the first light-emitting layer may be a thermal evaporation process. However, this is an example, and the deposition process of the first light-emitting layer is not limited to the above-mentioned example. The first light-emitting layer may be separated by the tip portion, formed on the partition wall PW, to form the first light-emitting pattern EP1 and a (1-1)-th dummy layer D11-I. The first light-emitting pattern EP1 may be formed on the first anode AE1 in the first light-emitting opening OP1-E and the first partition wall opening OP1-P. A portion of the (1-1)-th dummy layer D11-I may be formed inside the second and third partition wall openings OP2-P and OP3-P (or second and third light-emitting openings OP2-E and OP3-E), and another portion of the (1-1)-th dummy layer D11-I may be formed on the partition wall PW.

That is, in the forming of the first light-emitting pattern EP1, the (1-1)-th dummy layer D11-I, spaced apart from the first light-emitting pattern EP1, may also be formed. The (1-1)-th dummy layer D11-I may include an organic material. For example, the (1-1)-th dummy layer D11-I may include the same material as that of the first light-emitting pattern EP1. The (1-1)-th dummy layer D11-I may be formed through one process simultaneously with the first light-emitting pattern EP1, and formed separately from the first light-emitting pattern EP1 due to an undercut shape of the partition wall PW. That is, the first light-emitting pattern EP1 and the (1-1)-th dummy layer D11-I may be in a same layer as each other, such as by being respective patterns of a same material layer (e.g., the first light-emitting layer as a first light-emitting material layer).

The forming of the first cathode CE1 may include a deposition process of a first cathode layer. In an embodiment, the deposition process of the first cathode layer may be a sputtering process. However, this is an example, and the deposition process of the first cathode layer is not limited to the above-mentioned example. The first cathode layer may be separated by the tip portion, formed on the partition wall PW, to form the first cathode CE1 and a (2-1)-th dummy layer D21-I. The first cathode CE1 may be formed on the first light-emitting pattern EP1 in the first light-emitting opening OP1-E and the first partition wall opening OP1-P. A portion of the (2-1)-th dummy layer D21-I may be formed inside the second and third partition wall openings OP2-P and OP3-P (or second and third light-emitting openings OP2-E and OP3-E), and another portion of the (2-1)-th dummy layer D21-I may be formed on the partition wall PW.

That is, in the forming of the first cathode CE1, the (2-1)-th dummy layer D21-I, spaced apart from the first cathode CE1, may also be formed. The (2-1)-th dummy layer D21-I may include a conductive material. For example, the (2-1)-th dummy layer D21-I may include the same material as that of the first cathode CE1. The (2-1)-th dummy layer D21-I may be formed through one process simultaneously with the first cathode CE1, and formed separately from the first cathode CE1 due to the undercut shape of the partition wall PW. That is, the first cathode CE1 and the (2-1)-th dummy layer D21-I may be in a same layer as each other, such as by being respective patterns of a same material layer (e.g., the first cathode layer as a first cathode material layer).

The first anode AE1, the first light-emitting pattern EP1, and the first cathode CE1 may be stacked in sequence along a third direction DR3. The first anode AE1, the first light-emitting pattern EP1, and the first cathode CE1 may form the first light-emitting element ED1.

The (1-1)-th dummy layer D11-I and the (2-1)-th dummy layer D21-I may be stacked in sequence along the third direction DR3. The (1-1)-th dummy layer D11-I and the (2-1)-th dummy layer D21-I may form the first dummy layer DMP1-I, and dummy openings may be formed in the first dummy layer DMP1-I. Here, the providing of the first light-emitting element ED1 in the first partition wall opening OP1-P includes providing a first material layer of the first light-emitting element ED1 including a first material layer pattern (EP1 and/or CE L1) in the first partition wall opening, and a first dummy layer (D11-I and/or D21-I) of the first material layer which is inside the second partition wall opening, inside the third partition wall opening, and on the partition wall PW.

According to an embodiment of the invention, the method for providing the display panel DP may further include forming a capping pattern (not shown). The forming of the capping pattern may include a deposition process of a capping pattern layer, on the stacked structure of FIG. 8F, for example. The deposition process of the capping pattern layer may be a thermal evaporation process. The capping pattern layer may be separated by the tip portion, formed on the partition wall PW, to form the capping pattern and a (3-1)-th dummy layer. The capping pattern may be formed on the first cathode CE1 in the first partition wall opening OP1-P. A portion of the (3-1)-th dummy layer may be formed inside the second and third partition wall openings OP2-P and OP3-P, and another portion of the (3-1)-th dummy layer may be formed on the partition wall PW.

That is, in the forming of the capping pattern, the (3-1)-th dummy layer, spaced apart from the capping pattern, may also be formed. The (3-1)-th dummy layer may include a conductive material. For example, the (3-1)-th dummy layer may include the same material as that of the capping pattern. The (3-1)-th dummy layer may be formed through one process simultaneously with the capping pattern, and may be formed separately from the capping pattern due to the undercut shape of the partition wall PW. In this case, the first dummy layer DMP1-I may include the (1-1)-th dummy layer D11-I, the (2-1)-th dummy layer D21-I, and the (3-1)-th dummy layer.

Referring to FIGS. 8G to 8I, the method for providing the display panel DP according to an embodiment of the invention may include the forming of the first lower inorganic encapsulation pattern LIL1 which covers the first light-emitting element ED1. The forming of the first lower inorganic encapsulation pattern LIL1 may include depositing a first lower inorganic encapsulation layer LIL1-I, removing a portion of the first lower inorganic encapsulation layer LIL1-I not overlapping the first light-emitting element ED1, and removing the first dummy layer DMP1-I to form a first dummy region DMA1.

Referring to FIG. 8G, the forming of the first lower inorganic encapsulation pattern LIL1 may include the depositing of the first lower inorganic encapsulation layer LIL1-I. The first lower inorganic encapsulation layer LIL1-I may be formed through the deposition process. In an embodiment, the first lower inorganic encapsulation layer LIL1-I may be formed through a chemical vapor deposition (CVD) process. The first lower inorganic encapsulation layer LIL1-I may be formed to cover the first to third partition wall openings OP1-P, OP2-P, and OP3-P, and the partition wall PW, and to have a thickness TT1 of about 0.2 μm to about 1.0 μm.

Referring to FIG. 8H, the forming of the first lower inorganic encapsulation pattern LIL1 may include forming a second photoresist layer PR2 corresponding to the first light-emitting element ED1, and removing the portion of the first lower inorganic encapsulation layer LIL1-I not overlapping the first light-emitting element ED1.

In the forming of the second photoresist layer PR2, after forming a preliminary photoresist layer, the preliminary photoresist layer may be patterned, by using a photo mask, to form the second photoresist layer PR2. Through the patterning process, the second photoresist layer PR2 may be formed in a pattern corresponding to the first light-emitting element ED1. Here, the second photoresist layer PR2 corresponds to the first light-emitting element ED1 by being provided at the first partition wall opening OP1-P and an area adjacent thereto along an upper surface of the partition wall PW.

In the removing of the portion of the first lower inorganic encapsulation layer LIL1-I not overlapping the first light-emitting element ED1 (e.g., except for an area which corresponds to the first light-emitting element ED1 as described above), the first lower inorganic encapsulation layer LIL1-I may be patterned through dry etching using the second photoresist layer PR2 as a mask such that the portion of the first lower inorganic encapsulation layer LIL1-I, not overlapping the first light-emitting element ED1, is removed. The first lower inorganic encapsulation pattern LIL1 overlapping the first light-emitting element ED1 (e.g., at the first partition wall opening OP1-P and an area adjacent thereto) may be formed from the patterned first lower inorganic encapsulation layer LIL1-I. The first lower inorganic encapsulation pattern LIL1 may be a remaining portion of the first lower inorganic encapsulation layer LIL1-I.

Since the first lower inorganic encapsulation layer LIL1-I has a small thickness TT1 (for example, about 0.2 μm to about 1.0 μm), the process time for the dry etching may be minimalized. Therefore, in the patterning such that the portion of the first lower inorganic encapsulation layer LIL1-I, not overlapping the first light-emitting element ED1, is removed, an over etch phenomenon, which occurs in a region to be removed, may be reduced or eliminated.

Referring to FIG. 8I, the forming of the first lower inorganic encapsulation pattern LIL1 may include the removing of the first dummy layer DMP1-I (see FIG. 8H) to form the first dummy region DMA1.

The (2-1)-th dummy layer D21-I of the first dummy layer DMP1-I, formed inside the second and third partition wall openings OP2-P and OP3-P and on the partition wall PW, may be removed by performing a wet etching, to expose the first dummy layer DMP1-I, and the (1-1)-th dummy layer D11-I of the first dummy layer DMP1-I which is exposed may be removed by using a stripper. After this, the second photoresist layer PR2 (see FIG. 8H) may be removed. That is, an entirety of the first dummy layer DMP1-I in FIG. 8H may be removed from the stacked structure of FIG. 8H.

By removing the first dummy layer DMP1-I, the first dummy region DMA1 may be formed as a gap between an extended portion of the first lower inorganic encapsulation pattern LIL1 and an upper surface of the partition wall PW which faces the extended portion adjacent to the first partition wall opening OP1-P. A height H1 of the gap at the first dummy region DMA1 may correspond to the thickness of the first dummy layer DMP1-I (see FIG. 8F), that is, a sum of thicknesses of the (2-1)-th dummy layer D21-I and the (1-1)-th dummy layer D11-I. Here, the total thickness of the first dummy layer DMP1-I may correspond to the sum of thicknesses of the first light-emitting pattern EP1 which is in a same layer (and has a same thickness) as the (1-1)-th dummy layer D11-I and the first cathode CE1 which is in a same layer (and has a same thickness) as the (2-1)-th dummy layer D21-I.

By removal of the entirety of the first dummy layer DMP1-I from the stacked structure of FIG. 8H, various anode electrodes, sacrificial patterns, solid portions of the pixel-defining film and solid portions of the partition wall PW are exposed at light-emitting regions PXA other than the light-emitting region PXA to which the first light-emitting element ED1 corresponds.

Referring to FIG. 9A, the method for providing the display panel DP, according to an embodiment of the invention, may include the forming of the second light-emitting element ED2 in the second partition wall opening OP2-P. The forming of the second light-emitting element ED2 in the second partition wall opening OP2-P may include forming a second light-emitting pattern EP2 and forming a second cathode CE2. In addition, the forming of the second light-emitting element ED2 in the second partition wall opening OP2-P may include forming a second dummy layer DMP2-I inside the first and third partition wall openings OP1-P and OP3-P and on the partition wall PW.

The forming of the second light-emitting pattern EP2 may include a deposition process of a second light-emitting layer. In an embodiment, the deposition process of the second light-emitting layer may be a thermal evaporation process. However, this is an example, and the deposition process of the second light-emitting layer is not limited to the above-mentioned example. The second light-emitting layer may be separated by the tip portion, formed on the partition wall PW, to form the second light-emitting pattern EP2 and a (1-2)-th dummy layer D12-I. The second light-emitting pattern EP2 may be formed on the second anode AE2 in the second light-emitting opening OP2-E and the second partition wall opening OP2-P. A portion of the (1-2)-th dummy layer D12-I may be formed inside the first and third partition wall openings OP1-P and OP3-P (or first and third light-emitting openings OP1-E and OP3-E), and another portion of the (1-2)-th dummy layer D12-I may be formed on the partition wall PW.

That is, in the forming of the second light-emitting pattern EP2, the (1-2)-th dummy layer D12-I, spaced apart from the second light-emitting pattern EP2, may also be formed. The (1-2)-th dummy layer D12-I may include an organic material. For example, the (1-2)-th dummy layer D12-I may include the same material as that of the second light-emitting pattern EP2. The (1-2)-th dummy layer D12-I may be formed through one process simultaneously with the second light-emitting pattern EP2, and formed separately from the second light-emitting pattern EP2 due to the undercut shape of the partition wall PW.

The forming of the second cathode CE2 may include a deposition process of a second cathode layer. In an embodiment, the deposition process of the second cathode layer may be a sputtering process. However, this is an example, and the deposition process of the second cathode layer is not limited to the above-mentioned example. The second cathode layer may be separated by the tip portion, formed on the partition wall PW, to form the second cathode CE2 and a (2-2)-th dummy layer D22-I. The second cathode CE2 may be formed on the second light-emitting pattern EP2 in the second light-emitting opening OP2-E and the second partition wall opening OP2-P. A portion of the (2-2)-th dummy layer D22-I may be formed inside the first and third partition wall openings OP1-P and OP3-P (or first and third light-emitting openings OP1-E and OP3-E), and another portion of the (2-2)-th dummy layer D22-I may be formed on the partition wall PW.

That is, in the forming of the second cathode CE2, the (2-2)-th dummy layer D22-I, spaced apart from the second cathode CE2, may also be formed. The (2-2)-th dummy layer D22-I may include a conductive material. For example, the (2-2)-th dummy layer D22-I may include the same material as that of the second cathode CE2. The (2-2)-th dummy layer D22-I may be formed through one process simultaneously with the second cathode CE2, and formed separately from the second cathode CE2 due to the undercut shape of the partition wall PW.

The second anode AE2, the second light-emitting pattern EP2, and the second cathode CE2 may be stacked in sequence along a third direction DR3. The second anode AE2, the second light-emitting pattern EP2, and the second cathode CE2 may form the second light-emitting element ED2.

The (1-2)-th dummy layer D12-I and the (2-2)-th dummy layer D22-I may be stacked in sequence along the third direction DR3. The (1-2)-th dummy layer D12-I and the (2-2)-th dummy layer D22-I may form the second dummy layer DMP2-I, and dummy openings may be formed in the second dummy layer DMP2-I. Here, the providing of the second light-emitting element ED2 in the second partition wall opening OP2-P includes providing a second material layer of the second light-emitting element ED2 including a second material layer pattern (EP2 and/or CE2) in the second partition wall opening, and a second dummy layer (D12-I and/or D22-I) of the second material layer which is inside the first partition wall opening, inside the third partition wall opening, and on the partition wall PW.

According to an embodiment of the invention, similarly to that discussed above, the method for providing the display panel DP may further include forming a capping pattern, on the stacked structure of FIG. 9A for example. The forming of the capping pattern may include a deposition process of a capping pattern layer. The deposition process of the capping pattern layer may be a thermal evaporation process. The capping pattern layer may be separated by the tip portion, formed on the partition wall PW, to form the capping pattern and a (3-2)-th dummy layer. The capping pattern may be formed on the second cathode CE2 in the second partition wall opening OP2-P. A portion of the (3-2)-th dummy layer may be formed inside the first and third partition wall openings OP1-P and OP3-P, and another portion of the (3-2)-th dummy layer may be formed on the partition wall PW.

That is, in the forming of the capping pattern, the (3-2)-th dummy layer, spaced apart from the capping pattern, may also be formed. The (3-2)-th dummy layer may include a conductive material. For example, the (3-2)-th dummy layer may include the same material as that of the capping pattern. The (3-2)-th dummy layer may be formed through one process simultaneously with the capping pattern, and may be formed separately from the capping pattern due to the undercut shape of the partition wall PW. In this case, the second dummy layer DMP2-I may include the (1-2)-th dummy layer D12-I, the (2-2)-th dummy layer D22-I, and the (3-2)-th dummy layer.

Referring to FIGS. 9B to 9D, the method for providing the display panel DP, according to an embodiment of the invention, may include the forming of the second lower inorganic encapsulation pattern LIL2 which covers the second light-emitting element ED2. The forming of the second lower inorganic encapsulation pattern LIL2 may include depositing a second lower inorganic encapsulation layer LIL2-I, removing a portion of the second lower inorganic encapsulation layer LIL2-I not overlapping the second light-emitting element ED2, and removing the second dummy layer DMP2-I to form a second dummy region DMA2.

Referring to FIG. 9B, the forming of the second lower inorganic encapsulation pattern LIL2 may include the depositing of the second lower inorganic encapsulation layer LIL2-I. The second lower inorganic encapsulation layer LIL2-I may be formed through the deposition process. In an embodiment, the second lower inorganic encapsulation layer LIL2-I may be formed through a chemical vapor deposition (CVD) process. The second lower inorganic encapsulation layer LIL2-I may be formed to cover the first to third partition wall openings OP1-P, OP2-P, and OP3-P, and the partition wall PW, and to have a thickness TT2 of about 1.0 μm to about 1.5 μm. That is, the thickness TT2 of the second lower inorganic encapsulation layer LIL2-I may be larger than the thickness TT1 of the first lower inorganic encapsulation layer LIL1-I.

FIG. 9B exemplarily illustrates that the second lower inorganic encapsulation layer LIL2-I is formed apart from the first dummy region DMA1, but an embodiment of the invention is not limited thereto. For example, the second lower inorganic encapsulation layer LIL2-I may fill a portion of the first dummy region DMA1, or fill the entire first dummy region DMA1.

Referring to FIG. 9C, the forming of the second lower inorganic encapsulation pattern LIL2 may include forming a third photoresist layer PR3, and removing the portion of the second lower inorganic encapsulation layer LIL2-I not overlapping the second light-emitting element ED2. Here, the third photoresist layer PR3 corresponds to the second light-emitting element ED2 by being provided at the second partition wall opening OP2-P and an area adjacent thereto along an upper surface of the partition wall PW.

In the forming of the third photoresist layer PR3, after forming a preliminary photoresist layer, the preliminary photoresist layer may be patterned, by using a photo mask, to form the third photoresist layer PR3. Through the patterning process, the third photoresist layer PR3 may be formed in a pattern corresponding to the second light-emitting element ED2.

In the removing of the portion of the second lower inorganic encapsulation layer LIL2-I not overlapping the second light-emitting element ED2, the second lower inorganic encapsulation layer LIL2-I may be patterned through dry etching using the third photoresist layer PR3 as a mask such that the portion of the second lower inorganic encapsulation layer LIL2-I, not overlapping the second light-emitting element ED2, is removed. The second lower inorganic encapsulation pattern LIL2 overlapping the second light-emitting element ED2 may be formed from the patterned second lower inorganic encapsulation layer LIL2-I.

Referring to FIG. 9D, the forming of the second lower inorganic encapsulation pattern LIL2 may include removing the second dummy layer DMP2-I (see FIG. 9C) to form a second dummy region DMA2.

The (2-2)-th dummy layer D22-I of the second dummy layer DMP2-I, formed inside the first and third partition wall openings OP1-P and OP3.-P and on the partition wall PW, may be removed by performing a wet etching, and the (1-2)-th dummy layer D12-I of the second dummy layer DMP2-I may be removed by using a stripper. After this, the third photoresist layer PR3 (see FIG. 9C) may be removed. That is, an entirety of the second dummy layer DMP2-I in FIG. 9C may be removed from the stacked structure of FIG. 9C.

By removing the second dummy layer DMP2-I, the second dummy region DMA2 may be formed as a gap between the second lower inorganic encapsulation pattern LIL2 and the partition wall PW which defines the second partition wall opening OP2-P. A height H2 of the second dummy region DMA2 may correspond to the thickness of the second dummy layer DMP2-I (see FIG. 9A), and the thickness of the second dummy layer DMP2-I may correspond to a sum of the thicknesses of the second light-emitting pattern EP2 and the second cathode CE2.

The gap at a dummy region is an inlet at which gas used for etching flow. Referring to FIGS. 9C and 9D, as the height of the gap at the dummy region (or dummy layer) is greater during a process in a method of providing a display panel DP, inflow of gas used for dry etching becomes easier owing to the larger volume or space into which the gas may flow, so that the etching speed becomes higher. For example, since the height H2 of the second dummy region DMA2 (or second dummy layer DMP2-I) is greater than the height H1 of the first dummy region DMA1 (or first dummy layer DMP1-I (see FIG. 8H)), the speed of etching process for removing the portion of the second lower inorganic encapsulation layer LIL2-I (see FIG. 9B), not overlapping the second light-emitting element ED2, may be higher than the speed of etching process for removing the portion of the first lower inorganic encapsulation layer LIL1-I (see FIG. 8G) not overlapping the first light-emitting element ED1.

With a larger etching speed at the larger-height gap, over-etching may be undesirably occur. According to an embodiment of the invention, since the thickness TT2 of the second lower inorganic encapsulation layer LIL2-I which is etched at the larger-height gap is larger than the thickness TT1 of the first lower inorganic encapsulation layer LIL1-I, an over etch phenomenon, which occurs on the second lower inorganic encapsulation layer LIL2-I, may be reduced or eliminated.

Referring to FIG. 10A, the method for providing the display panel DP, according to an embodiment of the invention, may include the forming of the third light-emitting element ED3 in the third partition wall opening OP3-P. The forming of the third light-emitting element ED3 in the third partition wall opening OP3-P may include forming a third light-emitting pattern EP3 and forming a third cathode CE3. In addition, the forming of the third light-emitting element ED3 in the third partition wall opening OP3-P may include forming a third dummy layer DMP3-I inside the first and second partition wall openings OP1-P and OP2-P and on the partition wall PW.

The forming of the third light-emitting pattern EP3 may include a deposition process of a third light-emitting layer. In an embodiment, the deposition process of the third light-emitting layer may be a thermal evaporation process. However, this is an example, and the deposition process of the third light-emitting layer is not limited to the above-mentioned example. The third light-emitting layer may be separated by the tip portion, formed on the partition wall PW, to form the third light-emitting pattern EP3 and a (1-3)-th dummy layer D13-I. The third light-emitting pattern EP3 may be formed on the third anode AE3 in the third light-emitting opening OP3-E and the third partition wall opening OP3-P. A portion of the (1-3)-th dummy layer D13-I may be formed inside the first and second partition wall openings OP1-P and OP2-P (or first and second light-emitting openings OP1-E and OP2-E), and another portion of the (1-3)-th dummy layer D13-I may be formed on the partition wall PW.

That is, in the forming of the third light-emitting pattern EP3, the (1-3)-th dummy layer D13-I, spaced apart from the third light-emitting pattern EP3, may also be formed. The (1-3)-th dummy layer D13-I may include an organic material. For example, the (1-3)-th dummy layer D13-I may include the same material as that of the third light-emitting pattern EP3. The (1-3)-th dummy layer D13-I may be formed through one process simultaneously with the third light-emitting pattern EP3, and formed separately from the third light-emitting pattern EP3 due to the undercut shape of the partition wall PW.

The forming of the third cathode CE3 may include a deposition process of a third cathode layer. In an embodiment, the deposition process of the third cathode layer may be a sputtering process. However, this is an example, and the deposition process of the third cathode layer is not limited to the above-mentioned example. The third cathode layer may be separated by the tip portion, formed on the partition wall PW, to form the third cathode CE3 and a (2-3)-th dummy layer D23-I. The third cathode CE3 may be formed on the third light-emitting pattern EP3 in the third light-emitting opening OP3-E and the third partition wall opening OP3-P. A portion of the (2-3)-th dummy layer D23-I may be formed inside the first and second partition wall openings OP1-P and OP2-P (or first and second light-emitting openings OP1-E and OP2-E), and another portion of the (2-3)-th dummy layer D23-I may be formed on the partition wall PW.

That is, in the forming of the third cathode CE3, the (2-3)-th dummy layer D23-I, spaced apart from the third cathode CE3, may also be formed. The (2-3)-th dummy layer D23-I may include a conductive material. For example, the (2-3)-th dummy layer D23-I may include the same material as that of the third cathode CE3. The (2-3)-th dummy layer D23-I may be formed through one process simultaneously with the third cathode CE3, and formed separately from the third cathode CE3 due to the undercut shape of the partition wall PW.

The third anode AE3, the third light-emitting pattern EP3, and the third cathode CE3 may be stacked in sequence along a third direction DR3. The third anode AE3, the third light-emitting pattern EP3, and the third cathode CE3 may form the third light-emitting element ED3.

The (1-3)-th dummy layer D13-I and the (2-3)-th dummy layer D23-I may be stacked in sequence along the third direction DR3. The (1-3)-th dummy layer D13-I and the (2-3)-th dummy layer D23-I may form the third dummy layer DMP3-I, and dummy openings may be formed in the third dummy layer DMP3-I. Here, the providing of the third light-emitting element ED3 in the third partition wall opening OP3-P includes providing a third material layer of the third light-emitting element ED3 including a third material layer pattern (EP3 and/or CE3) in the third partition wall opening, and a third dummy layer (D13-I and/or D23-I) of the third material layer which is inside the first partition wall opening, inside the second partition wall opening, and on the partition wall PW.

According to an embodiment of the invention, similarly to that discussed above, the method for providing the display panel DP may further include forming a capping pattern on the stacked structure of FIG. 10A for example. The forming of the capping pattern may include a deposition process of a capping pattern layer. The deposition process of the capping pattern layer may be a thermal evaporation process. The capping pattern layer may be separated by the tip portion, formed on the partition wall PW, to form the capping pattern and a (3-3)-th dummy layer. The capping pattern may be formed on the third cathode CE3 in the third partition wall opening OP3-P. A portion of the (3-3)-th dummy layer may be formed inside the first and second partition wall openings OP1-P and OP2-P, and another portion of the (3-3)-th dummy layer may be formed on the partition wall PW.

That is, in the forming of the capping pattern, the (3-3)-th dummy layer, spaced apart from the capping pattern, may also be formed. The (3-3)-th dummy layer may include a conductive material. For example, the (3-3)-th dummy layer may include the same material as that of the capping pattern. The (3-3)-th dummy layer may be formed through one process simultaneously with the capping pattern, and may be formed separately from the capping pattern due to the undercut shape of the partition wall PW. In this case, the third dummy layer DMP3-I may include the (1-3)-th dummy layer D13-I, the (2-3)-th dummy layer D23-I, and the (3-3)-th dummy layer.

Referring to FIGS. 10B to 10D, the method for providing the display panel DP, according to an embodiment of the invention, may include the forming of the third lower inorganic encapsulation pattern LIL3 which covers the third light-emitting element ED3. The forming of the third lower inorganic encapsulation pattern LIL3 may include depositing a third lower inorganic encapsulation layer LIL3-I, removing a portion of the third lower inorganic encapsulation layer LIL3-I not overlapping the third light-emitting element ED3, and removing the third dummy layer DMP3-I to form a third dummy region DMA3.

Referring to FIG. 10B, the forming of the third lower inorganic encapsulation pattern LIL3 may include the depositing of the third lower inorganic encapsulation layer LIL3-I. The third lower inorganic encapsulation layer LIL3-I may be formed through the deposition process. In an embodiment, the third lower inorganic encapsulation layer LIL3-I may be formed through a chemical vapor deposition (CVD) process. The third lower inorganic encapsulation layer LIL3-I may be formed to cover the first to third partition wall openings OP1-P, OP2-P, and OP3-P, and the partition wall PW, and to have a thickness TT3 of about 1.0 μm to about 1.7 μm. That is, the thickness TT3 of the third lower inorganic encapsulation layer LIL3-I may be equal to or greater than the thickness TT2 (see FIG. 9B) of the second lower inorganic encapsulation layer LIL2-I (see FIG. 9B).

FIG. 10B exemplarily illustrates that the third lower inorganic encapsulation layer LIL3-I is formed apart from the first and second dummy regions DMA1 and DMA2, but an embodiment of the invention is not limited thereto. For example, the third lower inorganic encapsulation layer LIL3-I may fill a portion of the first dummy region DMA1 and/or the second dummy region DMA2, or fill the entire first dummy region DMA1 and/or second dummy region DMA2.

Referring to FIG. 10C, the forming of the third lower inorganic encapsulation pattern LIL3 may include forming a fourth photoresist layer PR4, and removing the portion of the third lower inorganic encapsulation layer LIL3-I not overlapping the third light-emitting element ED3. Here, the fourth photoresist layer PR4 corresponds to the third light-emitting element ED3 by being provided at the third partition wall opening OP3-P and an area adjacent thereto along an upper surface of the partition wall PW.

In the forming of the fourth photoresist layer PR4, after forming a preliminary photoresist layer, the preliminary photoresist layer may be patterned, by using a photo mask, to form the fourth photoresist layer PR4. Through the patterning process, the fourth photoresist layer PR4 may be formed in a pattern corresponding to the third light-emitting element ED3.

In the removing of the portion of the third lower inorganic encapsulation layer LIL3-I not overlapping the third light-emitting element ED3, the third lower inorganic encapsulation layer LIL3-I may be patterned through dry etching, using the fourth photoresist layer PR4 as a mask, such that the portion of the third lower inorganic encapsulation layer LIL3-I, not overlapping the third light-emitting element ED3, is removed. The third lower inorganic encapsulation pattern LIL3, overlapping the third light-emitting element ED3, may be formed from the patterned third lower inorganic encapsulation layer LIL3-I.

Referring to FIG. 10D, the forming of the third lower inorganic encapsulation pattern LIL3 may include removing the third dummy layer DMP3-I (see FIG. 10C) to form a third dummy region DMA3.

The (2-3)-th dummy layer D23-I of the third dummy layer DMP3-I, formed inside the first and second partition wall openings OP1-P and OP2-P and on the partition wall PW, may be removed by performing a wet etching, and the (1-3)-th dummy layer D13-I of the third dummy layer DMP3-I may be removed by using a stripper. After this, the fourth photoresist layer PR4 (see FIG. 10C) may be removed. That is, an entirety of the third dummy layer DMP3-I in FIG. 10C may be removed from the stacked structure of FIG. 10C.

By removing the third dummy layer DMP3-I, the third dummy region DMA3 may be formed as a gap between the third lower inorganic encapsulation pattern LIL3 and the partition wall PW which defines the third partition wall opening OP3-P. A height H3 of the third dummy region DMA3 may correspond to the thickness of the third dummy layer DMP3-I (see FIG. 10A), and the thickness of the third dummy layer DMP3-I may correspond to a sum of the thicknesses of the third light-emitting pattern EP3 and the third cathode CE3.

Referring to FIGS. 10C and 10D, as the height of the gap at the dummy region (or dummy layer) is greater during a process in a method of providing a display panel DP, inflow of gas used for dry etching becomes easier, so that the etching speed becomes higher. For example, since the height H3 of the third dummy region DMA3 (or third dummy layer DMP3-I) is greater than the height H2 of the second dummy region DMA2 (or second dummy layer DMP2-I (see FIG. 9C)), the speed of etching process for removing the portion of the third lower inorganic encapsulation layer LIL3-I (see FIG. 10B), not overlapping the third light-emitting element ED3, may be higher than the speed of etching process for removing the portion of the second lower inorganic encapsulation layer LIL2-I (see FIG. 9B) not overlapping the second light-emitting element ED2.

With a larger etching speed at the larger-height gap, over-etching may be undesirably occur. According to an embodiment of the invention, since the thickness TT3 of the third lower inorganic encapsulation layer LIL3-I is equal to or greater than the thickness TT2 of the second lower inorganic encapsulation layer LIL2-I, an over etch phenomenon, which occurs on the third lower inorganic encapsulation layer LIL3-I, may be reduced or eliminated.

Referring to FIG. 11, the method for providing the display panel DP, according to an embodiment of the invention, may include forming the organic encapsulation film OL and the upper inorganic encapsulation film UIL to complete the forming of the display panel DP. The organic encapsulation film OL may be formed by applying an organic material through inkjet, but an embodiment of the invention is not limited thereto. The organic encapsulation film OL provides a planarized upper surface. After this, the upper inorganic encapsulation film UIL may be formed by depositing an inorganic material. Through this, the display panel DP, which includes the base layer BL, the circuit element layer DP-CL, the display element layer DP-OLED, and the thin-film encapsulation layer TFE, may be formed.

According to what has been previously described, since the thickness of a second lower inorganic encapsulation layer LIL2 is larger than the thickness of a first lower inorganic encapsulation layer LIL1, an over etch phenomenon of the second lower inorganic encapsulation layer LIL2, may be reduced or eliminated. In addition, since the thickness of a third lower inorganic encapsulation layer LIL3 is equal to or greater than the thickness of the second lower inorganic encapsulation layer LIL2, an over etch phenomenon of the third lower inorganic encapsulation layer LIL3, may be reduced or eliminated.

Although the embodiments of the invention have been described, it is understood that the invention should not be limited to these embodiments but various changes and modifications can be made by one ordinary skilled in the art within the spirit and scope of the invention as hereinafter claimed. Therefore, the technical scope of the invention should not be limited to the contents described in the detailed description of the specification, but should be defined by the claims.

What is claimed is:

1. A display panel comprising:
a pixel-defining layer in which a first light-emitting opening and a second light-emitting opening are defined;
a partition wall which is on the pixel-defining layer and in which a first partition wall opening overlapping the first light-emitting opening and a second partition wall opening overlapping the second light-emitting opening are defined;
a first light-emitting element in the first partition wall opening, and including a first anode, a first light-emitting pattern and a first cathode;
a second light-emitting element in the second partition wall opening, and including a second anode, a second light-emitting pattern and a second cathode;
a first lower inorganic encapsulation pattern which covers the first light-emitting element; and
a second lower inorganic encapsulation pattern which is spaced apart from the first lower inorganic encapsulation pattern and covers the second light-emitting element,
wherein a thickness of the first lower inorganic encapsulation pattern is smaller than a thickness of the second lower inorganic encapsulation pattern.

2. The display panel of claim 1, wherein
the first light-emitting element emits blue light, and
the second light-emitting element emits green light.

3. The display panel of claim 1, wherein the thickness of the first lower inorganic encapsulation pattern is about 0.2 micrometer to about 1.0 micrometer.

4. The display panel of claim 1, wherein the thickness of the second lower inorganic encapsulation pattern is about 1.0 micrometer to about 1.5 micrometer.

5. The display panel of claim 1, wherein
adjacent to the first partition wall opening, the first lower inorganic encapsulation pattern is spaced apart from the partition wall with a first gap therebetween to define a first dummy region, and
adjacent to the second partition wall opening, the second lower inorganic encapsulation pattern is spaced apart from the partition wall with a second gap therebetween to define a second dummy region.

6. The display panel of claim 5, wherein along a thickness direction of the partition wall:
the first gap and the second gap respectively define heights of the first dummy region and the second dummy region, and
the height of the first dummy region is smaller than the height of the second dummy region.

7. The display panel of claim 5, further comprising:
a third light-emitting opening defined in the pixel-defining layer;
a third partition wall opening defined in the partition wall and overlapping the third light-emitting opening;
a third light-emitting element in the third partition wall opening, and including a third anode, a third light-emitting pattern and a third cathode; and
a third lower inorganic encapsulation pattern which is spaced apart from the first lower inorganic encapsulation pattern and the second lower inorganic encapsulation pattern and covers the third light-emitting element.

8. The display panel of claim 7, wherein a thickness of the third lower inorganic encapsulation pattern is equal to or greater than the thickness of the second lower inorganic encapsulation pattern.

9. The display panel of claim 7, wherein the third light-emitting element emits red light.

10. The display panel of claim 7, wherein the third lower inorganic encapsulation pattern has a thickness of about 1.0 micrometer to about 1.7 micrometer.

11. The display panel of claim 7, wherein adjacent to the third partition wall opening, the third lower inorganic encapsulation pattern is spaced apart from the partition wall with a third gap therebetween to define a third dummy region.

12. The display panel of claim 11, wherein along a thickness direction of the partition wall:
the second gap and the third gap respectively define heights of the second dummy region and the third dummy region, and
the height of the third dummy region is greater than the height of the second dummy region.

13. A method of providing a display panel, the method comprising:
providing a preliminary display panel including a pixel-defining layer in which light-emitting openings are defined, a first preliminary partition wall layer on the pixel-defining layer, and a second preliminary partition wall layer on the first preliminary partition wall layer;
etching the first preliminary partition wall layer and the second preliminary partition wall layer to form a partition wall in which a first partition wall opening, a second partition wall opening, and a third partition wall opening are defined respectively corresponding to the light-emitting openings;
providing a first light-emitting element in the first partition wall opening;
providing a first lower inorganic encapsulation pattern which covers the first light-emitting element;
providing a second light-emitting element in the second partition wall opening;
providing a second lower inorganic encapsulation pattern which is spaced apart from the first lower inorganic encapsulation pattern and covers the second light-emitting element;
providing a third light-emitting element in the third partition wall opening; and
providing a third lower inorganic encapsulation pattern which is spaced apart from the first lower inorganic encapsulation pattern and the second lower inorganic encapsulation pattern and covers the third light-emitting element,
wherein a thickness of the first lower inorganic encapsulation pattern is smaller than a thickness of the second lower inorganic encapsulation pattern.

14. The method of claim 13, wherein a thickness of the third lower inorganic encapsulation pattern is equal to or greater than the thickness of the second lower inorganic encapsulation pattern.

15. The method of claim 13, wherein the providing of the first light-emitting element in the first partition wall opening comprises providing a first material layer of the first light-emitting element including:
a first material layer pattern in the first partition wall opening, and
a first dummy layer of the first material layer which is inside the second partition wall opening, inside the third partition wall opening, and on the partition wall.

16. The method of claim 15, wherein the providing of the first lower inorganic encapsulation pattern comprises:
depositing a first lower inorganic encapsulation layer having a thickness of about 0.2 micrometer to about 1.0 micrometer covering each of the first material layer of the first light-emitting element, the first partition wall opening, the second partition wall opening, the third partition wall opening and the partition wall;
removing a portion of the first lower inorganic encapsulation layer which does not overlap the first light-emitting element; and
removing the first dummy layer to form a first gap which is between the first lower inorganic encapsulation pattern and the partition wall and adjacent to the first partition wall opening.

17. The method of claim 13, wherein the providing of the second light-emitting element in the second partition wall opening comprises providing a second material layer of the second light-emitting element including:
a second material layer pattern in the second partition wall opening, and
a second dummy layer of the second material layer which is inside the first partition wall opening, inside the third partition wall opening, and on the partition wall.

18. The method of claim 17, wherein the providing of the second lower inorganic encapsulation pattern comprises:
depositing a second lower inorganic encapsulation layer having a thickness of about 1.0 micrometer to about 1.5 micrometer covering each of the second material layer of the first light-emitting element, the first partition wall opening, the second partition wall opening, the third partition wall opening and the partition wall;
removing a portion of the second lower inorganic encapsulation layer which does not overlap the second light-emitting element; and
removing the second dummy layer to form a second gap which is between the second lower inorganic encapsulation pattern and the partition wall and adjacent to the second partition wall opening.

19. The method of claim 13, wherein the providing of the third light-emitting element in the third partition wall opening comprises providing a third material layer of the third light-emitting element including:
a third material layer pattern in the third partition wall opening, and
a third dummy layer of the third material layer which is inside the first partition wall opening, inside the second partition wall opening, and on the partition wall.

20. The method of claim 19, wherein the providing of the third lower inorganic encapsulation pattern comprises:
depositing a third lower inorganic encapsulation layer having a thickness of about 1.0 micrometer to about 1.7 micrometer covering each of the third material layer of the third light-emitting element, the first partition wall opening, the second partition wall opening, the third partition wall opening and the partition wall;
removing a portion of the third lower inorganic encapsulation layer which does not overlap the third light-emitting element; and
removing the third dummy layer to form a third gap which is between the third lower inorganic encapsulation pattern and the partition wall and adjacent to the third partition wall opening.
